(19) United States
(12) Patent Application Publication
(10) Pub. No.: US 2026/0040688 A1
(43) Pub. Date: Feb. 5, 2026

(54) DISPLAY DEVICE AND ELECTRONIC DEVICE INCLUDING THE SAME

(71) Applicant: Samsung Display Co., Ltd., Yongin-si (KR)

(72) Inventor: SUNKWUN SON, Yongin-si (KR)

(21) Appl. No.: 19/208,003

(22) Filed: May 14, 2025

(30) Foreign Application Priority Data
Jul. 30, 2024 (KR) 10-2024-0101134
Mar. 11, 2025 (KR) 10-2025-0031079

(51) Int. Cl. H10D 86/40; H01L 25/16; H10D 86/60; H10H 29/49

(52) U.S. Cl. CPC H10D 86/481; H01L 25/167; H10D 86/423; H10D 86/441; H10D 86/60; H10H 29/49

(57) ABSTRACT

A display device includes: a substrate; a lower conductive pattern on the substrate; a first active pattern on the lower conductive pattern; a first gate electrode on the first active pattern; a first capacitor on the first active pattern, and including: a first electrode electrically connected to the first gate electrode; and a second electrode on the first electrode, and to receive a driving voltage; a second active pattern on the first active pattern; a second capacitor on the first capacitor, and including: a first electrode electrically connected to the second active pattern; and a second electrode on the first electrode, and to receive a reference voltage; and a light-emitting element on the second capacitor.

### CROSS-REFERENCE TO RELATED APPLICATION

The present application claims priority to and the benefit of Korean Patent Application No. 10-2024-0101134, filed on Jul. 30, 2024, and Korean Patent Application No. 10-2025-0031079, filed on Mar. 11, 2025, in the Korean Intellectual Property Office, the entire disclosures of all of which are incorporated by reference herein.

### BACKGROUND

### 1. Field

Aspects of embodiments of the present disclosure relate to a display device that provides visual information, and an electronic device including the display device.

### 2. Description of the Related Art

With the development of information technology, the importance of a display device, which is a connection medium between a user and information, has been highlighted. For example, the use of display devices, such as a liquid crystal display (LCD) device, an organic light emitting diode (OLED) display device, a plasma display panel (PDP) device, a quantum dot display device, or the like, is increasing.

Recently, as the demand for a high-resolution display device has been increasing, a demand for a more efficient space arrangement, connection structure, and driving method between a thin film transistor, a capacitor, and lines included in the display device, and a demand for improving an image quality, are increasing. The above information disclosed in this Background section is for

enhancement of understanding of the background of the present disclosure, and therefore, it may contain information that does not constitute prior art.

### SUMMARY

One or more embodiments of the present disclosure may be directed to a display device having an improved resolution.

One or more embodiments of the present disclosure may be directed to an electronic device including the display device.

According to one or more embodiments of the present disclosure, a display device includes: a substrate; a lower conductive pattern on the substrate; a first active pattern on the lower conductive pattern; a first gate electrode on the first active pattern; a first capacitor on the first active pattern, and including: a first electrode electrically connected to the first gate electrode; and a second electrode on the first electrode, and configured to receive a driving voltage; a second active pattern on the first active pattern; a second capacitor on the first capacitor, and including: a first electrode electrically connected to the second active pattern; and a second electrode on the first electrode, and configured to receive a reference voltage; and a light-emitting element on the second capacitor.

In an embodiment, the first electrode of the second capacitor may be electrically connected to the lower conductive pattern through a gate connection electrode.

In an embodiment, the first capacitor may be located between the first active pattern and the second active pattern, and the second capacitor may be located on the second active pattern.

In an embodiment, the second capacitor may at least partially overlap with the first capacitor in a plan view.

In an embodiment, the second active pattern may at least partially overlap with the first active pattern in a plan view.

In an embodiment, the display device may further include a first voltage line on the second active pattern, and configured to: receive the driving voltage; and apply the driving voltage to the second electrode of the first capacitor through a driving voltage connection electrode.

In an embodiment, the second capacitor may be located between the first voltage line and the second active pattern.

In an embodiment, the first active pattern may include a silicon semiconductor material, and the second active pattern may include an oxide semiconductor material.

In an embodiment, the first active pattern may include: a first source area; a first drain area; a first channel area between the first source area and the first drain area; a third source area connected to the first drain area; a third drain area; and a third channel area between the third source area and the third drain area. The second active pattern may include: a second source area; a second drain area; and a second channel area between the second source area and the second drain area.

In an embodiment, the display device may further include a first connection pattern electrically connecting the third drain area of the first active pattern and the first gate electrode to each other.

In an embodiment, the first electrode of the first capacitor may be electrically connected to the third drain area of the first active pattern through the first connection pattern.

In an embodiment, the display device may further include a second connection pattern electrically connecting the first source area of the first active pattern and the second electrode of the first capacitor to each other.

In an embodiment, the first capacitor may be located between the second connection pattern and the second active pattern.

In an embodiment, the display device may further include a third connection pattern connected to the first drain area and the third source area of the first active pattern, and the third connection pattern may be electrically connected to the light-emitting element through a light-emitting element connection electrode.

In an embodiment, the lower conductive pattern, the first source area, the first channel area, the first drain area, and the first gate electrode may define a first transistor configured to provide a driving current to the light-emitting element.

In an embodiment, the lower conductive pattern may include a lower gate electrode of the first transistor, the first gate electrode may include an upper gate electrode of the first transistor, and the first channel area may include a channel of the first transistor.

In an embodiment, the display device may further include a second gate electrode between the second active pattern and the first electrode of the second capacitor. The second source area, the second channel area, the second drain area, and the second gate electrode may define a second transistor configured to apply a data voltage to the first transistor in response to a write gate signal.

In an embodiment, the second transistor may be configured to apply the data voltage to the first electrode of the second capacitor, and the first electrode of the second capacitor may be configured to apply the data voltage to the lower conductive pattern through a gate connection electrode.

In an embodiment, the display device may further include a third gate electrode located in a same layer as that of the first gate electrode. The third source area, the third channel area, the third drain area, and the third gate electrode may define a third transistor configured to diode-connect the first transistor in response to a compensation gate signal.

According to one or more embodiments of the present disclosure, an electronic device includes: a display device including a light-emitting element; and a processor configured to transmit an image data signal and an input control signal to the display device. The display device includes: a substrate; a lower conductive pattern on the substrate; a first active pattern on the lower conductive pattern; a first gate electrode on the first active pattern; a first capacitor on the first active pattern, and including: a first electrode electrically connected to the first gate electrode; and a second electrode on the first electrode, and configured to receive a driving voltage; a second active pattern on the first active pattern; a second capacitor on the first capacitor, and including: a first electrode electrically connected to the second active pattern; and a second electrode on the first electrode, and configured to receive a reference voltage; and the light-emitting element on the second capacitor.

According to some embodiments of the present disclosure, a display device may include a display panel that displays an image. The display panel may include a light-emitting element, and a pixel driving circuit connected to the light-emitting element. An area where one pixel driving circuit is arranged may be relatively reduced, and thus, an integration of the pixel driving circuit may be further improved. As the integration of the pixel driving circuits is improved, the resolution of the display device may be improved.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram illustrating a display device according to an embodiment of the present disclosure.

FIG. 2 is a circuit diagram illustrating a circuit structure of a pixel included in the display device of FIG. 1.

FIG. 3 is a cross-sectional view illustrating a display panel included in the display device of FIG. 1.

FIGS. 4-32 are layout views illustrating portions of the display panel of FIG. 3.

FIG. 33 is a block diagram illustrating an electronic device according to an embodiment of the present disclosure.

FIG. 34 is an exploded perspective view illustrating an electronic device according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense.

For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

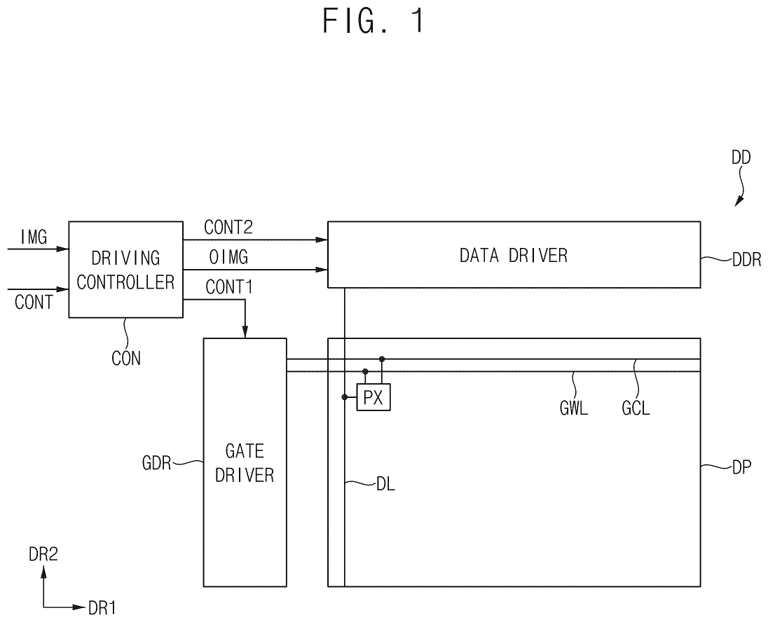

FIG. 1 is a block diagram illustrating a display device according to an embodiment of the present disclosure.

As used herein, a plane may be defined by a first direction DR1, and a second direction DR2 intersecting or crossing the first direction DR1. For example, the first direction DR1 and the second direction DR2 may be perpendicular to or substantially perpendicular to each other.

Referring to FIG. 1, a display device DD according to an embodiment of the present disclosure may include a display panel DP that displays an image, and a panel driver that drives the display panel DP. The panel driver may include a controller CON, a gate driver GDR, and a data driver DDR.

For example, the controller CON and the data driver DDR may be integrally formed with each other. For example, the controller CON, the gate driver GDR, and the data driver DDR may be integrally formed with each other. A driving module (e.g., a driving circuit) in which the controller CON and the data driver DDR are integrally formed with each other may be referred to as a timing controller embedded data driver (TED).

The display panel DP may include gate lines GWL and GCL, data lines DL, and pixels PX. The pixels PX may be electrically connected to the gate lines GWL and GCL and the data lines DL. Each of the pixels PX may generate light in response to a driving signal. For example, each of the gate lines GWL and GCL may extend in the first direction DR1, and each of the data lines DL may extend in the second direction DR2.

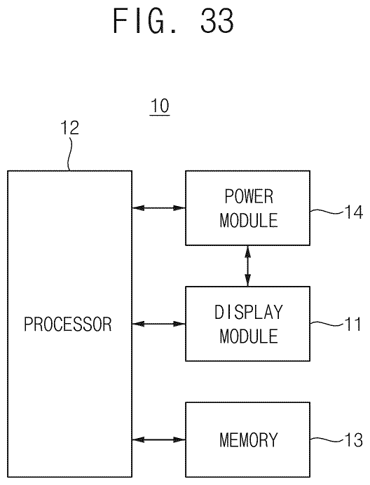

The controller CON may receive an image data signal IMG and an input control signal CONT from an external host processor (e.g., a processor 12 of FIG. 33). For example, the image data signal IMG may include red image data, green image data, and blue image data. The image data signal IMG may further include white image data. The input control signal CONT may include a vertical synchronization signal, a horizontal synchronization signal, a data enable signal, a master clock signal, or the like.

The controller CON may generate a first control signal CONT1, a second control signal CONT2, and output image data OIMG, based on the image data signal IMG and the input control signal CONT. The controller CON may output the first control signal CONT1 to the gate driver GDR. The first control signal CONT1 may include a vertical start signal and a gate clock signal. The controller CON may output the second control signal CONT2 and the output image data OIMG to the data driver DDR. The second control signal CONT2 may include an output data enable signal, a horizontal start signal, and a load signal.

The gate driver GDR may generate gate signals in response to the first control signal CONT1. The gate driver GDR may output the gate signals to the gate lines GWL and GCL. For example, each of the gate signals may include a gate-on voltage for turning on a transistor, and a gate-off voltage for turning off the transistor.

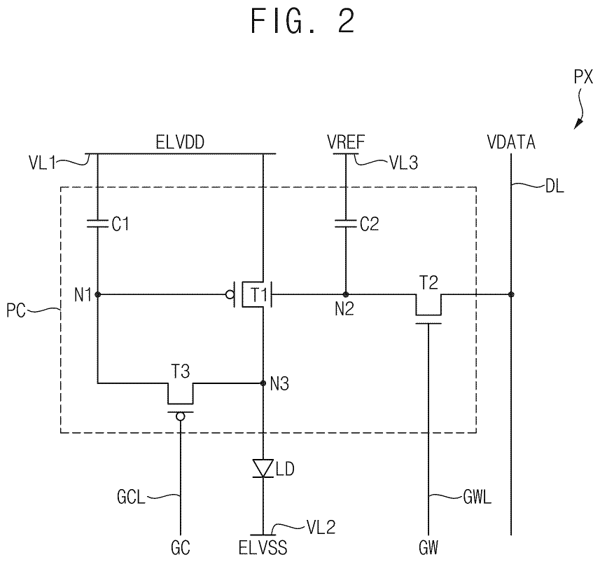

The data driver DDR may generate a data voltage VDATA (e.g., refer to FIG. 2) in response to the output image data OIMG and the second control signal CONT2. The data driver DDR may output the data voltage to the data lines DL.

FIG. 2 is a circuit diagram illustrating a circuit structure of a pixel included in the display device of FIG. 1.

Referring to FIGS. 1 and 2, the display panel DP may include the pixels PX. Light emitted from each of the pixels PX may be combined together to generate an image. For example, each of the pixels PX may emit any one of a red light, a green light, or a blue light, but the present disclosure is not limited thereto. Pixels PX that emit light of different colors from each other and are adjacent to each other may configure one unit pixel.

Each of the pixels PX may include a light-emitting element LD, and a pixel driving circuit PC connected to the light-emitting element LD. In an embodiment, the pixel driving circuit PC may include a first transistor T1, a second transistor T2, a third transistor T3, a first capacitor C1, and a second capacitor C2.

The pixel driving circuit PC may be connected to a first gate line GWL, a second gate line GCL, a data line DL, a first voltage line VL1, a second voltage line VL2, and a third voltage line VL3. The first gate line GWL may transmit a write gate signal GW. The second gate line GCL may transmit a compensation gate signal GC. The data line DL may transmit a data voltage VDATA. The first voltage line VL1 may transmit a driving voltage ELVDD having a relatively higher voltage level. The second voltage line VL2 may transmit a common voltage ELVSS having a relatively lower voltage level. The third voltage line VL3 may transmit a reference voltage VREF.

The first transistor T1 may include an upper gate electrode, a lower gate electrode, a first electrode, and a second electrode. The upper gate electrode of the first transistor T1 may be connected to a first node N1. The lower gate electrode of the first transistor T1 may be connected to a second node N2. The first electrode of the first transistor T1 may be connected to the first voltage line VL1 to receive the driving voltage ELVDD. The second electrode of the first transistor T1 may be connected to a third node N3. The first transistor T1 may provide a driving current to the light-emitting element LD. For example, the first transistor T1 may be referred to as a driving transistor. In an embodiment, the first transistor T1 may be a p-type transistor, but the present disclosure is not limited thereto.

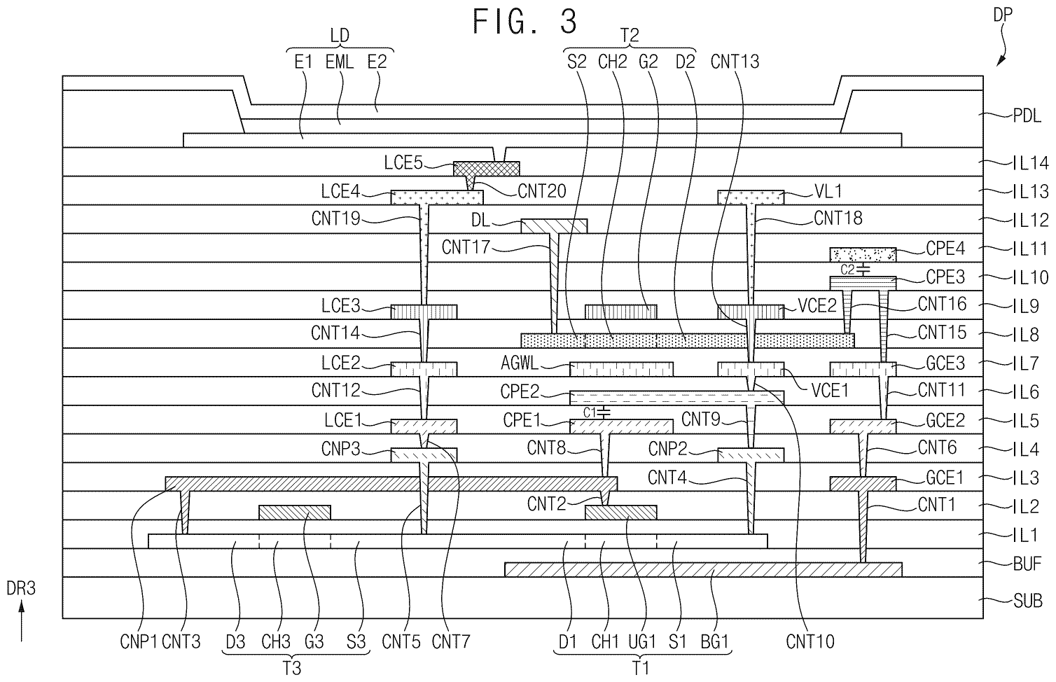

The first capacitor C1 may include a first electrode (e.g., a first electrode CPE1 of FIG. 3) and a second electrode (e.g., a second electrode CPE2 of FIG. 3). The first electrode of the first capacitor C1 may be connected to the first node N1. The second electrode of the first capacitor C1 may be connected to the first voltage line VL1 to receive the driving voltage ELVDD. The first capacitor C1 may serve to receive the driving voltage ELVDD, may transmit the voltage to the upper gate electrode of the first transistor T1, and may maintain or substantially maintain the voltage. For example, the first capacitor C1 may be referred to as a storage capacitor.

The second transistor T2 may include a gate electrode, a first electrode, and a second electrode. The gate electrode of the second transistor T2 may receive the write gate signal GW through the first gate line GWL. The first electrode of the second transistor T2 may be connected to the data line DL to receive the data voltage VDATA. The second electrode of the second transistor T2 may be connected to the second node N2.

The second transistor T2 may be turned on or turned off in response to the write gate signal GW. In an embodiment, while the second transistor T2 is turned on, the second electrode of the second transistor T2 may provide the data voltage VDATA to the second node N2. In other words, the second transistor T2 may provide the data voltage VDATA to the lower gate electrode of the first transistor T1. Accordingly, the second transistor T2 may drive the first transistor T1. For example, the second transistor T2 may be referred to as a writing transistor. In an embodiment, the second transistor T2 may be an n-type transistor, but the present disclosure is not limited thereto.

The second capacitor C2 may include a first electrode (e.g., a first electrode CPE3 of FIG. 3) and a second electrode (e.g., a second electrode CPE4 of FIG. 3). The first electrode of the second capacitor C2 may be connected to the second node N2. The second electrode of the second capacitor C2 may be connected to the third voltage line VL3 to receive the reference voltage VREF. The second capacitor C2 may serve to hold a voltage of the second node N2, so that the voltage of the second node N2 does not fluctuate and has a constant or substantially constant voltage even when a peripheral signal fluctuates. For example, the second capacitor C2 may be referred to as a hold capacitor.

The third transistor T3 may include a gate electrode, a first electrode, and a second electrode. The gate electrode of the third transistor T3 may receive the compensation gate signal GC through the second gate line GCL. The first electrode of the third transistor T3 may be connected to the third node N3. The second electrode of the third transistor T3 may be connected to the first node N1.

The third transistor T3 may be turned on or turned off in response to the compensation gate signal GC. While the third transistor T3 is turned on, the third transistor T3 may diode-connect the first transistor T1. In other words, the third transistor T3 may form a path for compensating a threshold voltage of the first transistor T1. For example, the third transistor T3 may be referred to as a compensation transistor. In an embodiment, the third transistor T3 may be a p-type transistor, but the present disclosure is not limited thereto.

The light-emitting element LD may include an anode and a cathode. The anode of the light-emitting element LD may be connected to the third node N3. The cathode of the light-emitting element LD may be connected to the second voltage line VL2 to receive the common voltage ELVSS. The light-emitting element LD may generate light having a luminance corresponding to the driving current.

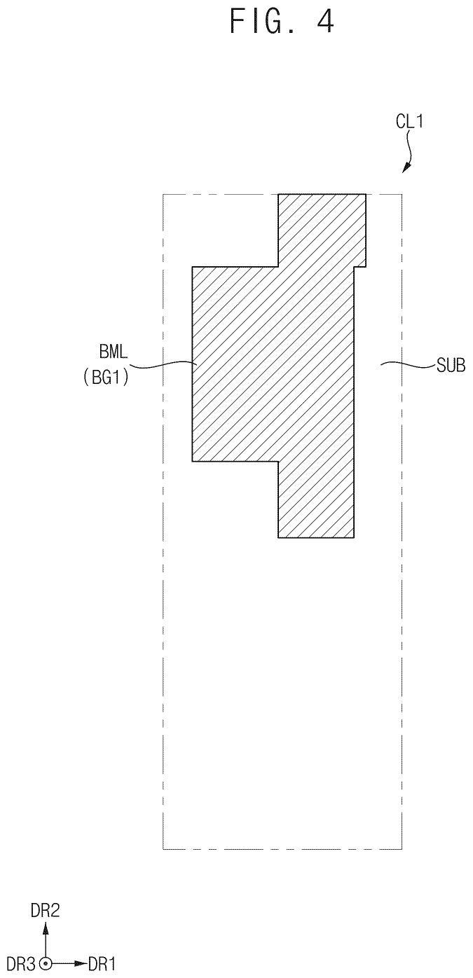

FIG. 3 is a cross-sectional view illustrating a display panel included in the display device of FIG. 1. For example, FIG. 3 is a cross-sectional view illustrating one pixel PX as described above with reference to FIG. 2. FIGS. 4 through 32 are layout views illustrating portions of the display panel of FIG. 3. FIGS. 4 through 32 selectively illustrate some layers among a plurality of layers included in the display panel DP of FIG. 3.

Hereinafter, the arrangement structure of transistors, capacitors, and lines included in the pixel driving circuit PC of FIG. 2 will be described in more detail with reference to FIGS. 3 to 32. A structure of one pixel driving circuit PC as described hereinafter with reference to FIGS. 3 to 32 may be repeatedly arranged within the display panel DP.

As used herein, a plane may be defined by the first direction DR1 and the second direction DR2 as described above, and a direction normal to or substantially normal to the plane, or in other words, a thickness direction of the display panel DP, may be a third direction DR3. In other words, the third direction DR3 may be perpendicular to or substantially perpendicular to each of the first direction DR1 and the second direction DR2.

Referring to FIGS. 3 to 32, the display panel DP may include a substrate SUB, a circuit element layer arranged on the substrate SUB, and a light-emitting element layer arranged on the circuit element layer.

The circuit element layer may include a first conductive layer CL1, a buffer layer BUF, a first active layer ACL1, a first insulating layer IL1, a second conductive layer CL2, a second insulating layer IL2, a third conductive layer CL3, a third insulating layer IL3, a fourth conductive layer CL4, a fourth insulating layer IL4, a fifth conductive layer CL5, a fifth insulating layer IL5, a sixth conductive layer CL6, a sixth insulating layer IL6, a seventh conductive layer CL7, a seventh insulating layer IL7, a second active layer ACL2, an eighth insulating layer IL8, an eighth conductive layer CL8, a ninth insulating layer IL9, a ninth conductive layer CL9, a tenth insulating layer IL10, a tenth conductive layer CL10, an eleventh insulating layer IL11, an eleventh conductive layer CL11, a twelfth insulating layer IL12, a twelfth conductive layer CL12, a thirteenth insulating layer IL13, a thirteenth conductive layer CL13, and a fourteenth insulating layer IL14, which may be sequentially arranged along the third direction DR3.

The light-emitting element layer may include the light-emitting element LD and a pixel defining layer PDL. The light-emitting element LD may include a pixel electrode E1, a light-emitting layer EML, and a common electrode E2.

The substrate SUB may include a transparent material or an opaque material. For example, the substrate SUB may be formed of a transparent resin substrate. A polyimide substrate may be an example of the transparent resin substrate. In this case, the polyimide substrate may include a first organic layer, a first barrier layer, a second organic layer, or the like. In an embodiment, the substrate SUB may include a quartz substrate (e.g., a synthetic quartz substrate, a fluorine-doped quartz substrate, or the like), a calcium fluoride substrate, a soda-lime glass substrate, a non-alkali glass substrate, or the like. These may be used alone or in any suitable combination with each other.

FIG. 4 is a layout view illustrating the first conductive layer CL1.

As illustrated in FIGS. 3 and 4, the first conductive layer CL1 may be arranged on the substrate SUB. The first conductive layer CL1 may include a conductive material, such as a metal, an alloy, a conductive metal nitride, a conductive metal oxide, a transparent conductive oxide, or the like. Examples of the conductive material that may be used as the first conductive layer CL1 may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in any suitable combination with each other.

The first conductive layer CL1 may include a lower conductive pattern BML. In other words, the lower conductive pattern BML may be arranged on the substrate SUB. In an embodiment, as described in more detail below, a portion of the lower conductive pattern BML may be a lower gate electrode BG1 of the first transistor T1.

The buffer layer BUF may be arranged on the first conductive layer CL1. The buffer layer BUF may cover the lower conductive pattern BML. The buffer layer BUF may prevent or substantially prevent diffusion of metal atoms or impurities from the substrate SUB to the first conductive layer CL1. In addition, the buffer layer BUF may obtain a uniform or substantially uniform first active pattern ACT1 by controlling a heat transfer rate during a crystallization process for forming the first active pattern ACT1. For example, the buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), or the like. These may be used alone or in any suitable combination with each other.

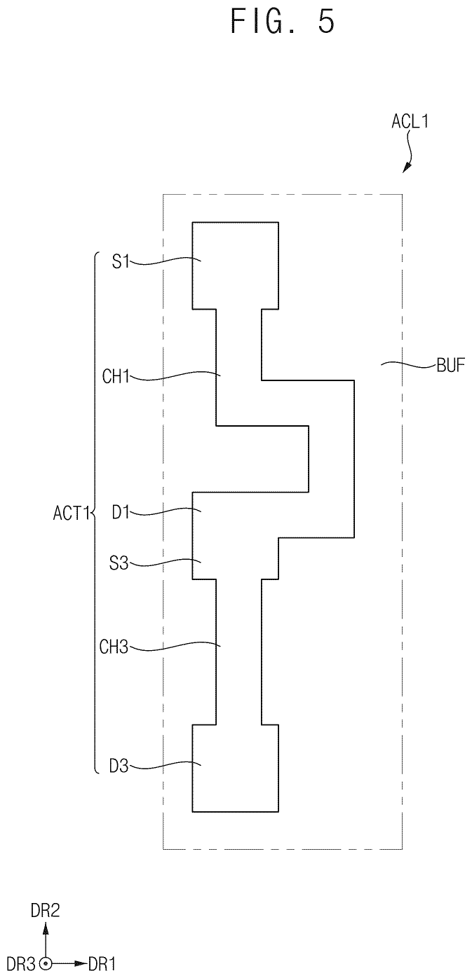

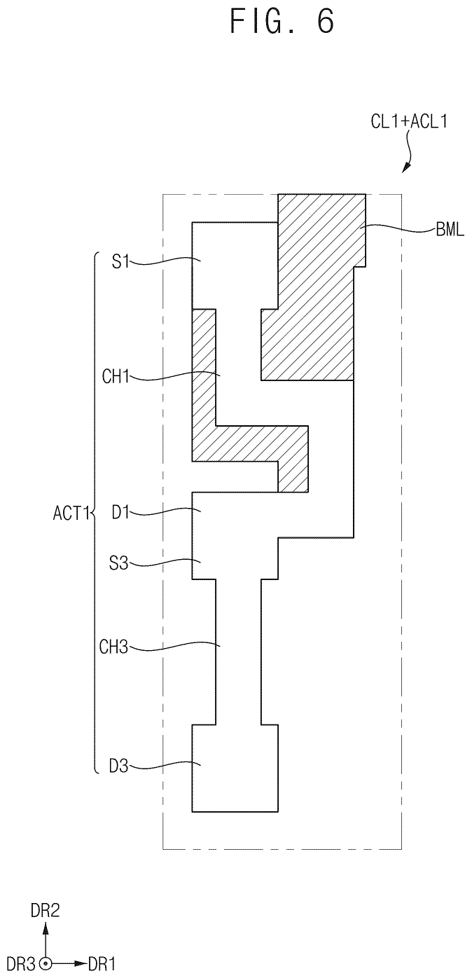

FIG. 5 is a layout view illustrating the first active layer ACL1. FIG. 6 is a layout view in which the first active layer ACL1 is further arranged on the first conductive layer CL1 of FIG. 4.

As illustrated in FIGS. 3, 5, and 6, the first active layer ACL1 may be arranged on the first conductive layer CL1. For example, the first active layer ACL1 may be arranged on the buffer layer BUF.

In an embodiment, the first active layer ACL1 may include a silicon semiconductor material. Examples of the silicon semiconductor material that may be used as the first active layer ACL1 may include amorphous silicon, polycrystalline silicon, or the like.

The first active layer ACL1 may include the first active pattern ACT1. The first active pattern ACT1 may be arranged on the lower conductive pattern BML. The first active pattern ACT1 may include a first source area S1, a first channel area CH1, a first drain area D1, a third source area S3, a third channel area CH3, and a third drain area D3.

The first channel area CH1 may be positioned between the first source area S1 and the first drain area D1. The third channel area CH3 may be positioned between the third source area S3 and the third drain area D3. For example, the first channel area CH1 may have a shape that may be bent along the first direction DR1 and the second direction DR2, and the third channel area CH3 may have a shape that extends in a straight or substantially straight line along the second direction DR2, but the present disclosure is not limited thereto.

In an embodiment, the first source area S1, the first drain area D1, the third source area S3, and the third drain area D3 may be areas that are doped with p-type dopants, but the present disclosure is not limited thereto. The first drain area D1 and the third source area S3 may be connected to each other.

The first source area S1 may be the first electrode of the first transistor T1, the first drain area D1 may be the second electrode of the first transistor T1, and the first channel area CH1 may be a channel of the first transistor T1.

The third source area S3 may be the first electrode of the third transistor T3, the third drain area D3 may be the second electrode of the third transistor T3, and the third channel area CH3 may be a channel of the third transistor T3.

In an embodiment, a portion of the lower conductive pattern BML may overlap with the first channel area CH1 of the first active pattern ACT1 in a plan view. The portion of the lower conductive pattern BML overlapping with the first channel area CH1 may be the lower gate electrode BG1 of the first transistor T1.

The first insulating layer IL1 may be arranged on the first active layer ACL1. The first insulating layer IL1 may cover the first active pattern ACT1. The first insulating layer IL1 may include an inorganic insulating material and/or an organic insulating material.

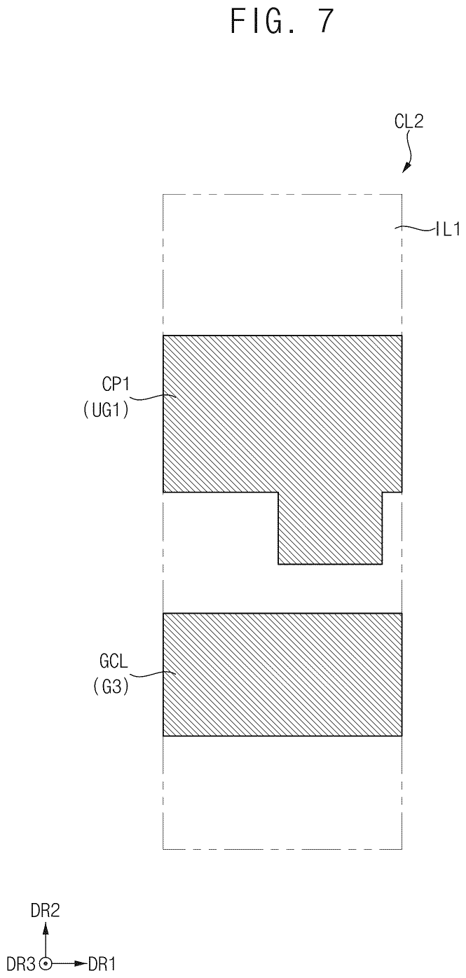

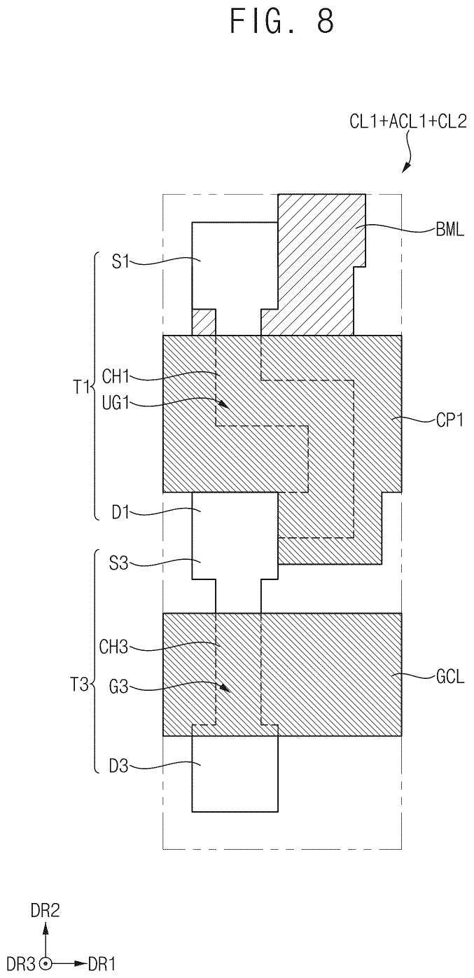

FIG. 7 is a layout view illustrating the second conductive layer CL2. FIG. 8 is a layout view in which the second conductive layer CL2 is further arranged on the first active layer ACL1 of FIG. 6.

As illustrated in FIGS. 3, 7, and 8, the second conductive layer CL2 may be arranged on the first active layer ACT1. For example, the second conductive layer CL2 may be arranged on the first insulating layer IL1.

The second conductive layer CL2 may include a conductive material, such as a metal, an alloy, a conductive metal nitride, a conductive metal oxide, a transparent conductive oxide, or the like. These may be used alone or in any suitable combination with each other. For example, the second conductive layer CL2 may be referred to as a first gate conductive layer.

The second conductive layer CL2 may include a first conductive pattern CP1 and the second gate line GCL. The first conductive pattern CP1 and the second gate line GCL may be spaced apart from each other in a plan view.

As illustrated in FIGS. 6 and 8, a portion of the first conductive pattern CP1 may overlap with the first channel area CH1 of the first active pattern ACT1 in a plan view. The portion of the first conductive pattern CP1 overlapping with the first channel area CH1 may be a first gate electrode UG1 of the first transistor T1. The first gate electrode UG1 may be arranged on the first active pattern ACT1. The first gate electrode UG1 may be the upper gate electrode of the first transistor T1 of FIG. 2.

The second gate line GCL may extend in the first direction DR1. The second gate line GCL may be spaced apart from the first conductive pattern CP1 in the second direction DR2. The compensation gate signal GC of FIG. 2 may be applied to the second gate line GCL.

A portion of the second gate line GCL may overlap with the third channel area CH3 of the first active pattern ACT1 in a plan view. The portion of the second gate line GCL overlapping with the third channel area CH3 may be a third gate electrode G3. The third gate electrode G3 may be the gate electrode of the third transistor T3 of FIG. 2. In an embodiment, the third gate electrode G3 may be arranged in the same layer as that of the first gate electrode UG1.

The second insulating layer IL2 may be arranged on the second conductive layer CL2. The second insulating layer IL2 may cover the first conductive pattern CP1 and the second gate line GCL. The second insulating layer IL2 may include an inorganic insulating material and/or an organic insulating material.

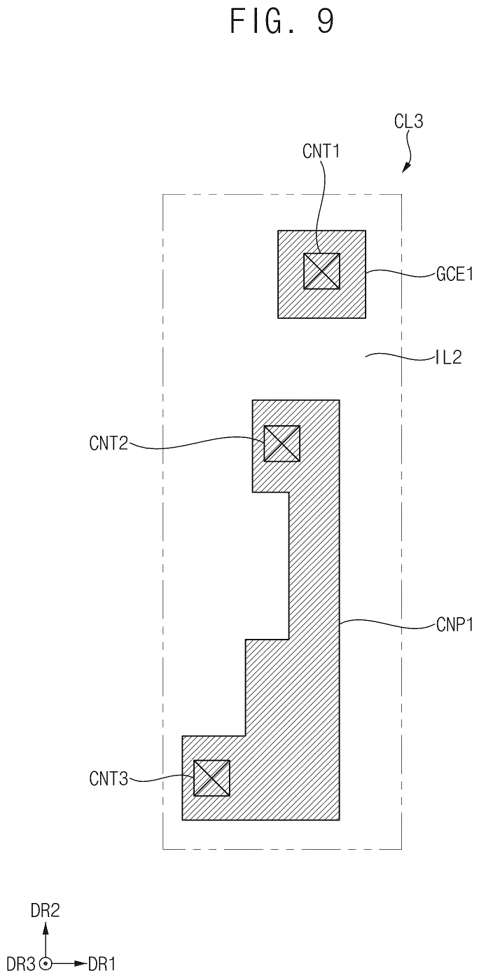

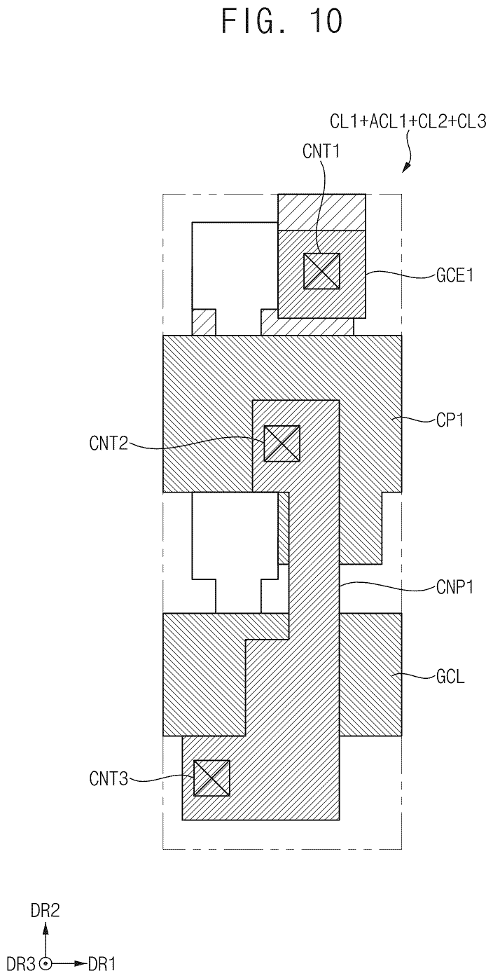

FIG. 9 is a layout view illustrating the third conductive layer CL3. FIG. 10 is a layout view in which the third conductive layer CL3 is further arranged on the second conductive layer CL2 of FIG. 8.

As illustrated in FIGS. 3, 9, and 10, the third conductive layer CL3 may be arranged on the second conductive layer CL2. For example, the third conductive layer CL3 may be arranged on the second insulating layer IL2.

The third conductive layer CL3 may include a conductive material, such as a metal, an alloy, a conductive metal nitride, a conductive metal oxide, a transparent conductive oxide, or the like. These may be used alone or in any suitable combination with each other. For example, the third conductive layer CL3 may be referred to as a second gate conductive layer.

The third conductive layer CL3 may include a first gate connection electrode GCE1 and a first connection pattern CNP1. The first gate connection electrode GCE1 and the first connection pattern CNP1 may be spaced apart from each other in a plan view.

As illustrated in FIGS. 4 and 10, the first gate connection electrode GCE1 may overlap with the lower conductive pattern BML in a plan view. The first gate connection electrode GCE1 may be connected to the lower conductive pattern BML through a first contact hole CNT1 that penetrates a lower insulating layer (e.g., the buffer layer BUF, the first insulating layer IL1, and the second insulating layer IL2). In other words, the first contact hole CNT1 may expose a portion of the lower conductive pattern BML, and a portion of the first gate connection electrode GCE1 may contact the portion of the lower conductive pattern BML through the first contact hole CNT1.

As illustrated in FIGS. 8 and 10, the first connection pattern CNP1 may overlap with the first conductive pattern CP1 and the third drain area D3 of the first active pattern ACT1 in a plan view.

The first connection pattern CNP1 may be connected to the first conductive pattern CP1 through a second contact hole CNT2 that penetrates a lower insulating layer (e.g., the second insulating layer IL2). In other words, the second contact hole CNT2 may expose a portion of the first conductive pattern CP1, and a first portion of the first connection pattern CNP1 may contact the portion of the first conductive pattern CP1 through the second contact hole CNT2.

The first connection pattern CNP1 may be connected to the third drain area D3 of the first active pattern ACT1 through a third contact hole CNT3 that penetrates a lower insulating layer (e.g., the first insulating layer IL1 and the second insulating layer IL2). In other words, the third contact hole CNT3 may expose a portion of the third drain area D3, and a second portion of the first connection pattern CNP1 may contact the portion of the third drain area D3 through the third contact hole CNT3.

Accordingly, the first connection pattern CNP1 may electrically connect the third drain area D3 of the first active pattern ACT1 (e.g., the second electrode of the third transistor T3) and the first conductive pattern CP1 (e.g., the first gate electrode UG1 of the first transistor T1) to each other.

The third insulating layer IL3 may be arranged on the third conductive layer CL3. The third insulating layer IL3 may cover the first gate connection electrode GCE1 and the first connection pattern CNP1. The third insulating layer IL3 may include an inorganic insulating material and/or an organic insulating material.

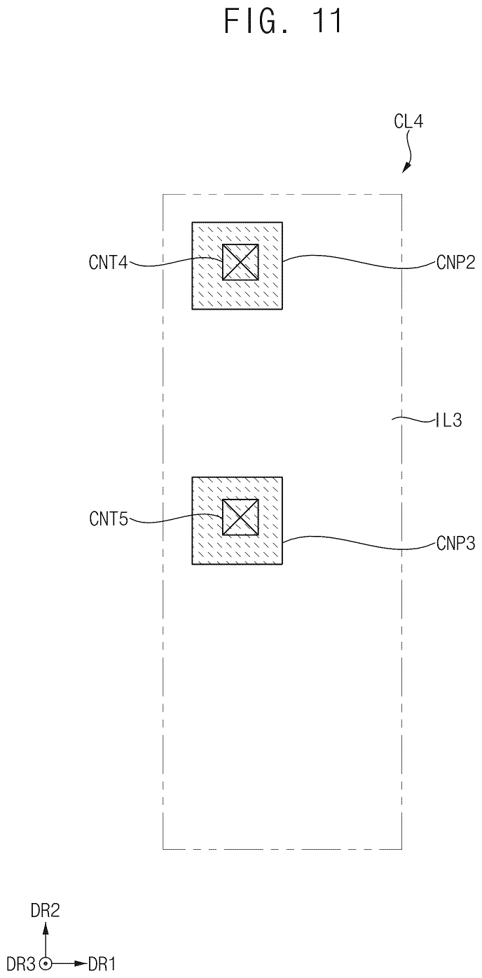

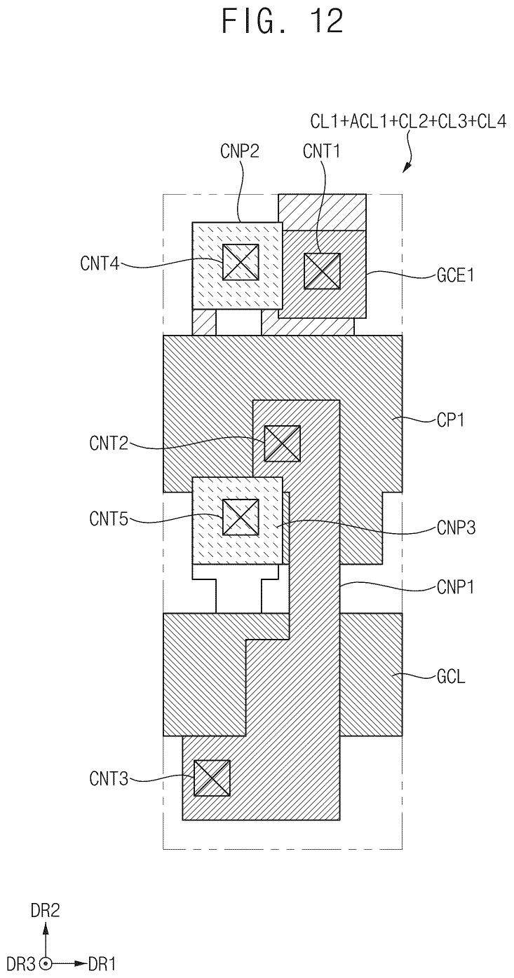

FIG. 11 is a layout view illustrating the fourth conductive layer CL4. FIG. 12 is a layout view in which the fourth conductive layer CL4 is further arranged on the third conductive layer CL3 of FIG. 10.

As illustrated in FIGS. 3, 11, and 12, the fourth conductive layer CL4 may be arranged on the third conductive layer CL3. For example, the fourth conductive layer CL4 may be arranged on the third insulating layer IL3.

The fourth conductive layer CL4 may include a conductive material, such as a metal, an alloy, a conductive metal nitride, a conductive metal oxide, a transparent conductive oxide, or the like. These may be used alone or in any suitable combination with each other. For example, the fourth conductive layer CL4 may be referred to as a third gate conductive layer.

The fourth conductive layer CL4 may include a second connection pattern CNP2 and a third connection pattern CNP3. The second connection pattern CNP2 and the third connection pattern CNP3 may be spaced apart from each other in a plan view.

As illustrated in FIGS. 10 and 12, the second connection pattern CNP2 may overlap with the first source area S1 of the first active pattern ACT1 in a plan view. The second connection pattern CNP2 may be connected to the first source area S1 of the first active pattern ACT1 through a fourth contact hole CNT4 that penetrates a lower insulating layer (e.g., the first insulating layer IL1, the second insulating layer IL2, and the third insulating layer IL3). In other words, the fourth contact hole CNT4 may expose a portion of the first source area S1, and a portion of the second connection pattern CNP2 may contact the portion of the first source area S1 through the fourth contact hole CNT4. As described in more detail below, the second connection pattern CNP2 may be connected to a third conductive pattern CP3 (e.g., a second electrode CPE2 of the first capacitor C1) through a ninth contact hole CNT9. Accordingly, the second connection pattern CNP2 may electrically connect the first source area S1 of the first active pattern ACT1 and the third conductive pattern CP3 (e.g., the second electrode CPE2 of the first capacitor C1) to each other.

The third connection pattern CNP3 may overlap with the first drain area D1 and the third source area S3 of the first active pattern ACT1 in a plan view. The third connection pattern CNP3 may be connected to the first drain area D1 (e.g., the second electrode of the first transistor T1) and the third source area S3 (e.g., the first electrode of the third transistor T3) of the first active pattern ACT1 through a fifth contact hole

CNT5 that penetrates a lower insulating layer (e.g., the first insulating layer IL1, the second insulating layer IL2, and the third insulating layer IL3). In other words, the fifth contact hole CNT5 may expose a portion of each of the first drain area D1 and the third source area S3, and a portion of the third connection pattern CNP3 may contact the portion of each of the first drain area D1 and the third source area S3 through the fifth contact hole CNT5. As described in more detail below, the third connection pattern CNP3 may be electrically connected to the light-emitting element LD through light-emitting element connection electrodes LCE1, LCE2, LCE3, LCE4, and LCE5.

The fourth insulating layer IL4 may be arranged on the fourth conductive layer CL4. The fourth insulating layer IL4 may cover the second connection pattern CNP2 and the third connection pattern CNP3. The fourth insulating layer IL4 may include an inorganic insulating material and/or an organic insulating material.

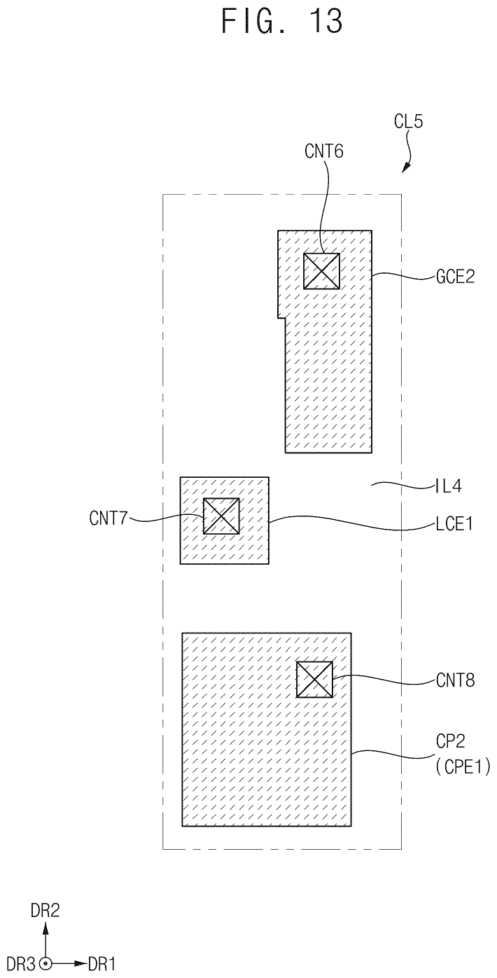

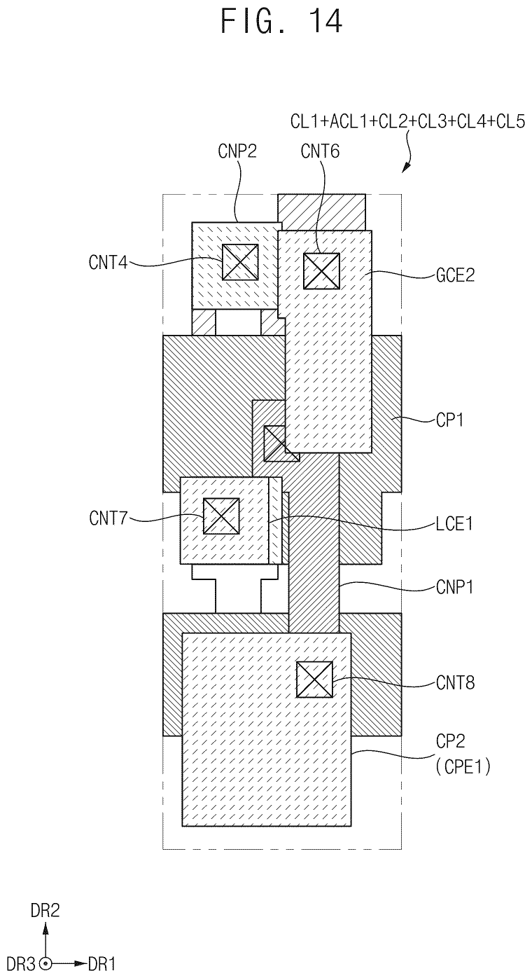

FIG. 13 is a layout view illustrating the fifth conductive layer CL5. FIG. 14 is a layout view in which the fifth conductive layer CL5 is further arranged on the fourth conductive layer CL4 of FIG. 12.

As illustrated in FIGS. 3, 13, and 14, the fifth conductive layer CL5 may be arranged on the fourth conductive layer CL4. For example, the fifth conductive layer CL5 may be arranged on the fourth insulating layer IL4.

The fifth conductive layer CL5 may include a conductive material, such as a metal, an alloy, a conductive metal nitride, a conductive metal oxide, a transparent conductive oxide, or the like. These may be used alone or in any suitable combination with each other. For example, the fifth conductive layer CL5 may be referred to as a fourth gate conductive layer.

The fifth conductive layer CL5 may include a second gate connection electrode GCE2, a first light-emitting element connection electrode LCE1, and a second conductive pattern CP2. The second gate connection electrode GCE2, the first light-emitting element connection electrode LCE1, and the second conductive pattern CP2 may be spaced apart from each other in a plan view.

As illustrated in FIGS. 10 and 14, the second gate connection electrode GCE2 may overlap with the first gate connection electrode GCE1 in a plan view. The second gate connection electrode GCE2 may be connected to the first gate connection electrode GCE1 through a sixth contact hole CNT6 that penetrates a lower insulating layer (e.g., the third insulating layer IL3 and the fourth insulating layer IL4). In other words, the sixth contact hole CNT6 may expose a portion of the first gate connection electrode GCE1, and a portion of the second gate connection electrode GCE2 may contact the portion of the first gate connection electrode GCE1.

As illustrated in FIGS. 12 and 14, the first light-emitting element connection electrode LCE1 may overlap with the third connection pattern CNP3 in a plan view. The first light-emitting element connection electrode LCE1 may be connected to the third connection pattern CNP3 through a seventh contact hole CNT7 that penetrates a lower insulating layer (e.g., the fourth insulating layer IL4). In other words, the seventh contact hole CNT7 may expose a portion of the third connection pattern CNP3, and a portion of the first light-emitting element connection electrode LCE1 may contact the portion of the third connection pattern CNP3.

As illustrated in FIGS. 10 and 14, the second conductive pattern CP2 may overlap with the first connection pattern CNP1 in a plan view. The second conductive pattern CP2 may be connected to the first connection pattern CNP1 through an eighth contact hole CNT8 that penetrates a lower insulating layer (e.g., the third insulating layer IL3 and the fourth insulating layer IL4). In other words, the eighth contact hole CNT8 may expose a portion of the first connection pattern CNP1, and a portion of the second conductive pattern CP2 may contact the portion of the first connection pattern CNP1 through the eighth contact hole CNT8.

Accordingly, the second conductive pattern CP2 may be electrically connected to the third drain area D3 of the first active pattern ACT1 (e.g., the second electrode of the third transistor T3) and the first conductive pattern CP1 (e.g., the first gate electrode UG1 of the first transistor T1) through the first connection pattern CNP1. As described in more detail below, the second conductive pattern CP2 may be a first electrode CPE1 of the first capacitor C1.

The fifth insulating layer IL5 may be arranged on the fifth conductive layer CL5. The fifth insulating layer IL5 may cover the second gate connection electrode GCE2, the first light-emitting element connection electrode LCE1, and the second conductive pattern CP2. The fifth insulating layer IL5 may include an inorganic insulating material and/or an organic insulating material.

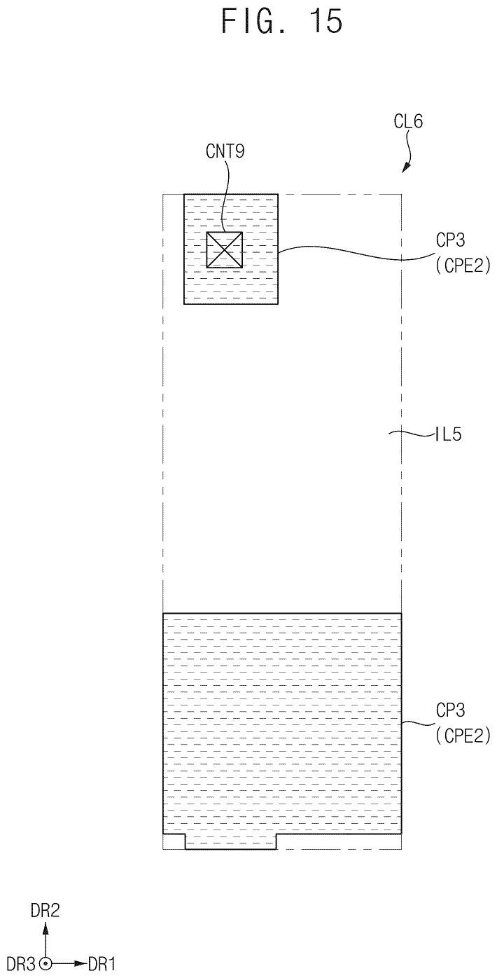

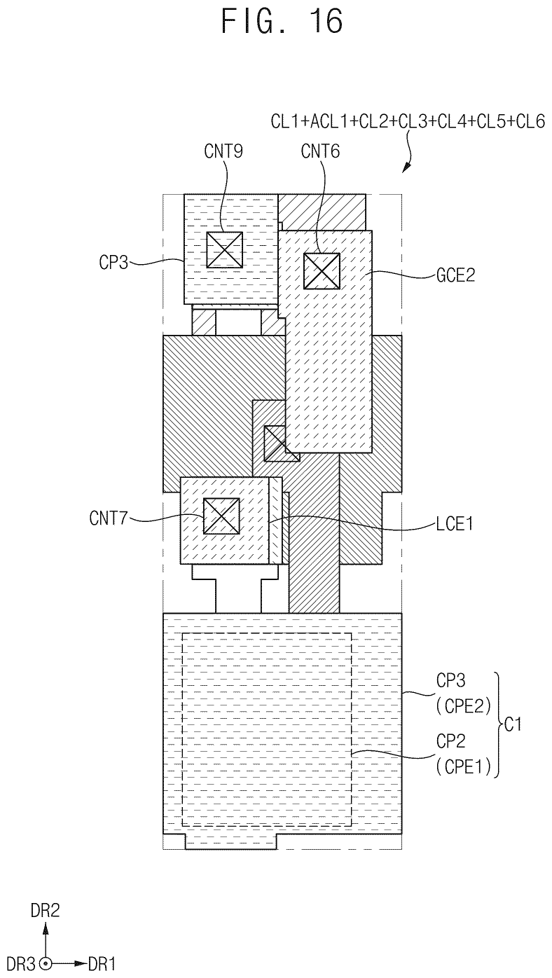

FIG. 15 is a layout view illustrating the sixth conductive layer CL6. FIG. 16 is a layout view in which the sixth conductive layer CL6 is further arranged on the fifth conductive layer CL5 of FIG. 14.

As illustrated in FIGS. 3, 15, and 16, the sixth conductive layer CL6 may be arranged on the fifth conductive layer CL5. For example, the sixth conductive layer CL6 may be arranged on the fifth insulating layer IL5.

The sixth conductive layer CL6 may include a conductive material, such as a metal, an alloy, a conductive metal nitride, a conductive metal oxide, a transparent conductive oxide, or the like. These may be used alone or in any suitable combination with each other. For example, the sixth conductive layer CL6 may be referred to as a first capacitor electrode layer.

The sixth conductive layer CL6 may include the third conductive pattern CP3. As illustrated in FIGS. 12 and 16, the third conductive pattern CP3 may overlap with the second connection pattern CNP2 in a plan view. The third conductive pattern CP3 may be connected to the second connection pattern CNP2 through the ninth contact hole CNT9 that penetrates a lower insulating layer (e.g., the fourth insulating layer IL4 and the fifth insulating layer IL5). In other words, the ninth contact hole CNT9 may expose a portion of the second connection pattern CNP2, and a portion of the third conductive pattern CP3 may contact the portion of the second connection pattern CNP2 through the ninth contact hole CNT9.

Accordingly, the third conductive pattern CP3 may be electrically connected to the first source area S1 of the first active pattern ACT1 (e.g., the first electrode of the first transistor T1) through the second connection pattern CNP2.

As illustrated in FIGS. 14 and 16, the third conductive pattern CP3 may overlap with the second conductive pattern CP2 in a plan view. The third conductive pattern CP3 may be spaced apart from the second conductive pattern CP2 by the fifth insulating layer IL5. The second conductive pattern CP2 and the third conductive pattern CP3 may form the first capacitor C1. In other words, the second conductive pattern CP2 may be the first electrode CPE1 of the first capacitor C1, and the third conductive pattern CP3 may be a second electrode CPE2 of the first capacitor C1.

In an embodiment, the first capacitor C1 may be arranged between the first active pattern ACT1 and a second active pattern ACT2.

In an embodiment, the first capacitor C1 may be arranged between the second connection pattern CNP2 and the second active pattern ACT2.

In an embodiment, the third conductive pattern CP3 may be formed as the separate first capacitor electrode layer that does not configure the transistors (e.g., the first to third transistors T1, T2, and T3). In other words, the second electrode CPE2 of the first capacitor C1 may be formed in the separate first capacitor electrode layer that does not configure the transistors. Accordingly, the capacitance of the first capacitor C1 may be relatively increased.

The sixth insulating layer IL6 may be arranged on the sixth conductive layer CL6. The sixth insulating layer IL6 may cover the third conductive pattern CP3. The sixth insulating layer IL6 may include an inorganic insulating material and/or an organic insulating material.

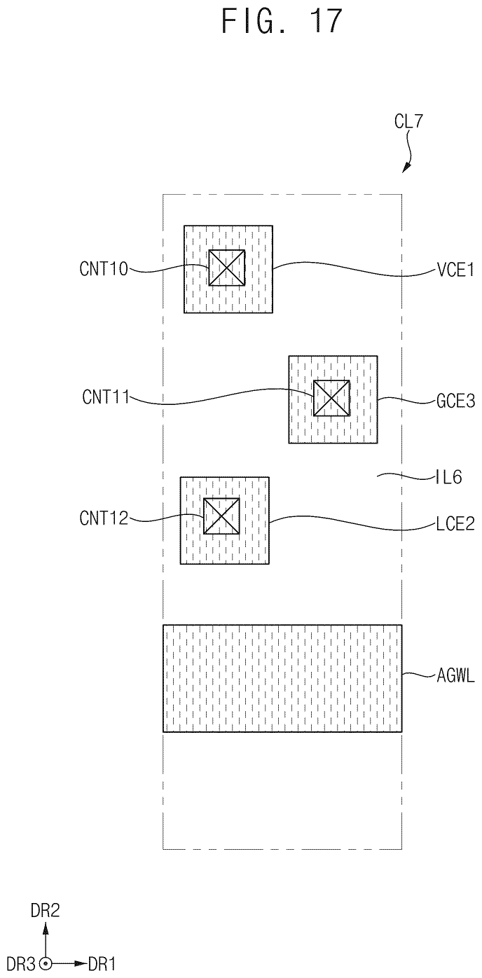

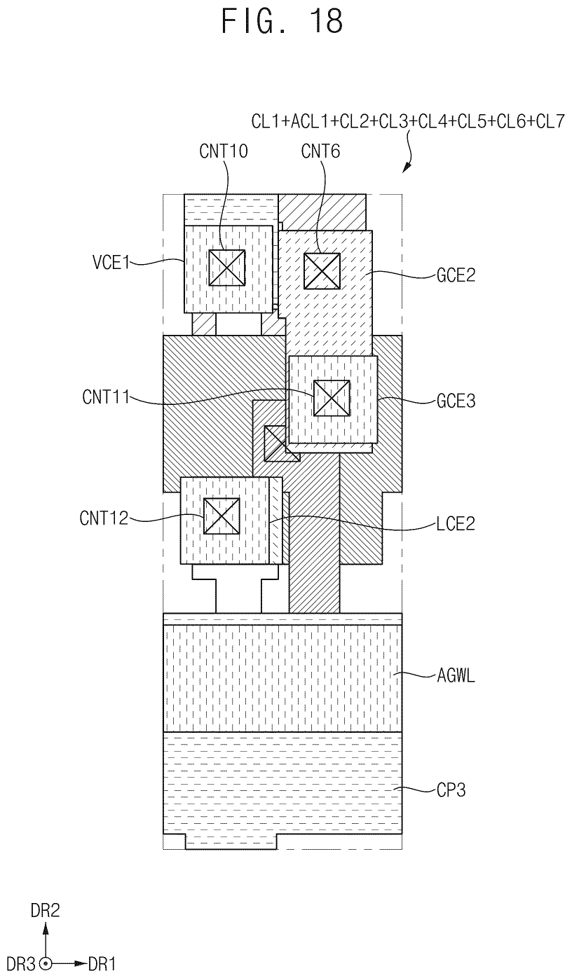

FIG. 17 is a layout view illustrating the seventh conductive layer CL7. FIG. 18 is a layout view in which the seventh conductive layer CL7 is further arranged on the sixth conductive layer CL6 of FIG. 16.

As illustrated in FIGS. 3, 17, and 18, the seventh conductive layer CL7 may be arranged on the sixth conductive layer CL6. For example, the seventh conductive layer CL7 may be arranged on the sixth insulating layer IL6.

The seventh conductive layer CL7 may include a conductive material, such as a metal, an alloy, a conductive metal nitride, a conductive metal oxide, a transparent conductive oxide, or the like. These may be used alone or in any suitable combination with each other. For example, the seventh conductive layer CL7 may be referred to as a fifth gate conductive layer.

The seventh conductive layer CL7 may include a first driving voltage connection electrode VCE1, a third gate connection electrode GCE3, a second light-emitting element connection electrode LCE2, and an auxiliary gate line AGWL. The first driving voltage connection electrode VCE1, the third gate connection electrode GCE3, the second light-emitting element connection electrode LCE2, and the auxiliary gate line AGWL may be spaced apart from each other in a plan view.

As illustrated in FIGS. 16 and 18, the first driving voltage connection electrode VCE1 may overlap with the third conductive pattern CP3 in a plan view. The first driving voltage connection electrode VCE1 may be connected to the third conductive pattern CP3 through a tenth contact hole CNT10 that penetrates a lower insulating layer (e.g., the sixth insulating layer IL6). In other words, the tenth contact hole CNT10 may expose a portion of the third conductive pattern CP3, and a portion of the first driving voltage connection electrode VCE1 may contact the portion of the third conductive pattern CP3 through the tenth contact hole CNT10.

As illustrated in FIGS. 14 and 18, the third gate connection electrode GCE3 may overlap with the second gate connection electrode GCE2 in a plan view. The third gate connection electrode GCE3 may be connected to the second gate connection electrode GCE2 through an eleventh contact hole CNT11 that penetrates a lower insulating layer (e.g., the fifth insulating layer IL5 and the sixth insulating layer IL6). In other words, the eleventh contact hole CNT11 may expose a portion of the second gate connection electrode GCE2, and a portion of the third gate connection electrode GCE3 may contact the portion of the second gate connection electrode GCE2.

As illustrated in FIGS. 14 and 18, the second light-emitting element connection electrode LCE2 may overlap with the first light-emitting element connection electrode LCE1 in a plan view. The second light-emitting element connection electrode LCE2 may be connected to the first light-emitting element connection electrode LCE1 through a twelfth contact hole CNT12 that penetrates a lower insulating layer (e.g., the fifth insulating layer IL5 and the sixth insulating layer IL6). In other words, the twelfth contact hole CNT12 may expose a portion of the first light-emitting element connection electrode LCE1, and a portion of the second light-emitting element connection electrode LCE2 may contact the portion of the first light-emitting element connection electrode LCE1 through the twelfth contact hole CNT12.

The auxiliary gate line AGWL may extend in the first direction DR1. The auxiliary gate line AGWL may be connected to the first gate line GWL arranged in the eighth conductive layer CL8 described in more detail below through a contact hole. The write gate signal GW of FIG. 2 may be applied to the auxiliary gate line AGWL. In an embodiment, the auxiliary gate line AGWL may serve as a light blocking pattern for the second active pattern ACT2.

The seventh insulating layer IL7 may be arranged on the seventh conductive layer CL7. The seventh insulating layer IL7 may cover the first driving voltage connection electrode VCE1, the third gate connection electrode GCE3, the second light-emitting element connection electrode LCE2, and the auxiliary gate line AGWL. The seventh insulating layer IL7 may include an inorganic insulating material and/or an organic insulating material.

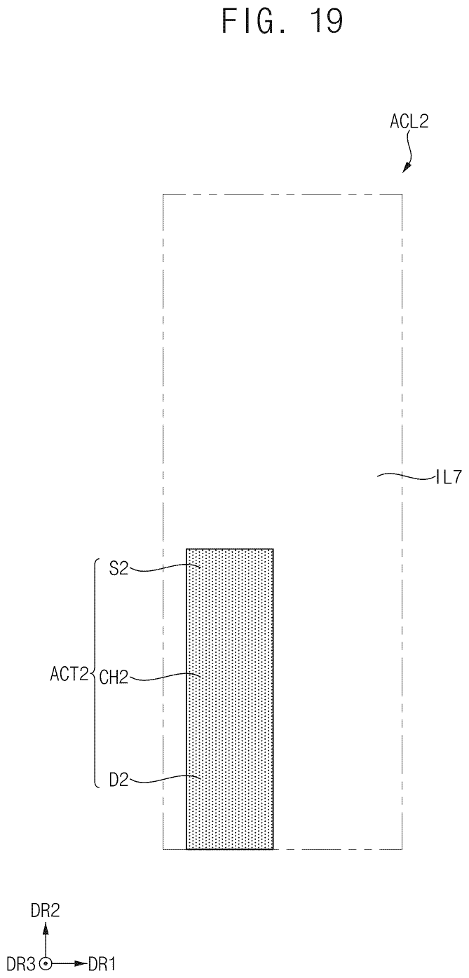

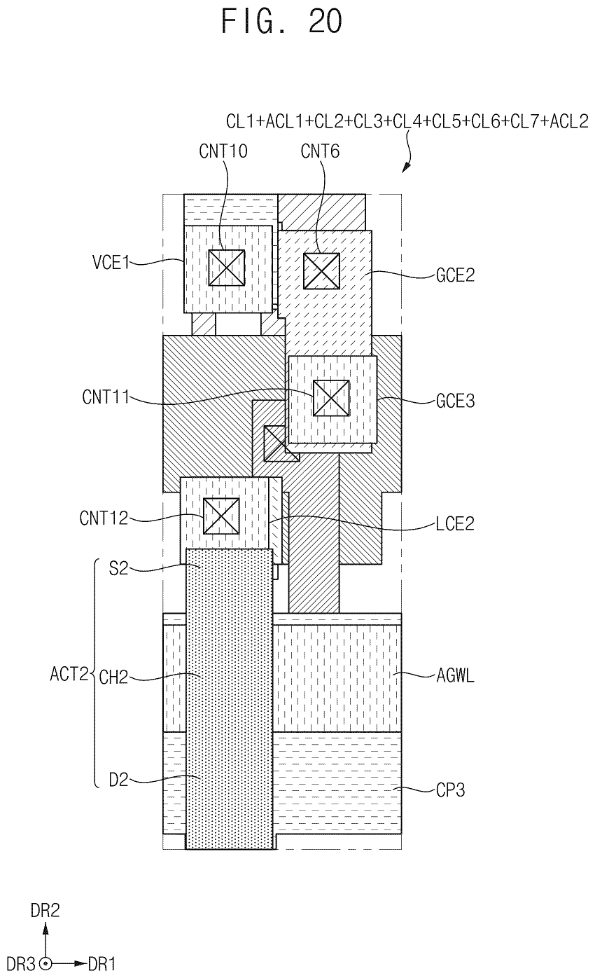

FIG. 19 is a layout view illustrating the second active layer ACL2. FIG. 20 is a layout view in which the second active layer ACL2 is further arranged on the seventh conductive layer CL7 of FIG. 18.

As illustrated in FIGS. 3, 19, and 20, the second active layer ACL2 may be arranged on the seventh conductive layer CL7. For example, the second active layer ACL2 may be arranged on the seventh insulating layer IL7.

In an embodiment, the second active layer ACL2 may include an oxide semiconductor material. For example, the second active layer ACL2 may include at least one oxide of indium (In), gallium (Ga), tin (Sn), zirconium (Zr), vanadium (V), hafnium (Hf), cadmium (Cd), germanium (Ge), chromium (Cr), titanium (Ti), or zinc (Zn).

The second active layer ACL2 may include the second active pattern ACT2. The second active pattern ACT2 may include a second source area S2, a second channel area CH2, and a second drain area D2. The second channel area CH2 may be positioned between the second source area S2 and the second drain area D2.

The second source area S2 may be the first electrode of the second transistor T2, the second drain area D2 may be the second electrode of the second transistor T2, and the second channel area CH2 may be a channel of the second transistor T2. The second channel area CH2 may overlap with the auxiliary gate line AGWL in a plan view.

In an embodiment, the second active pattern ACT2 may at least partially overlap with the first active pattern ACT1 in a plan view. Accordingly, the integration of the pixel driving circuits PC (e.g., refer to FIG. 2) included in the display panel DP may be further improved.

The eighth insulating layer IL8 may be arranged on the second active layer ACL2. The eighth insulating layer IL8 may cover the second active pattern ACT2. The eighth insulating layer IL8 may include an inorganic insulating material and/or an organic insulating material.

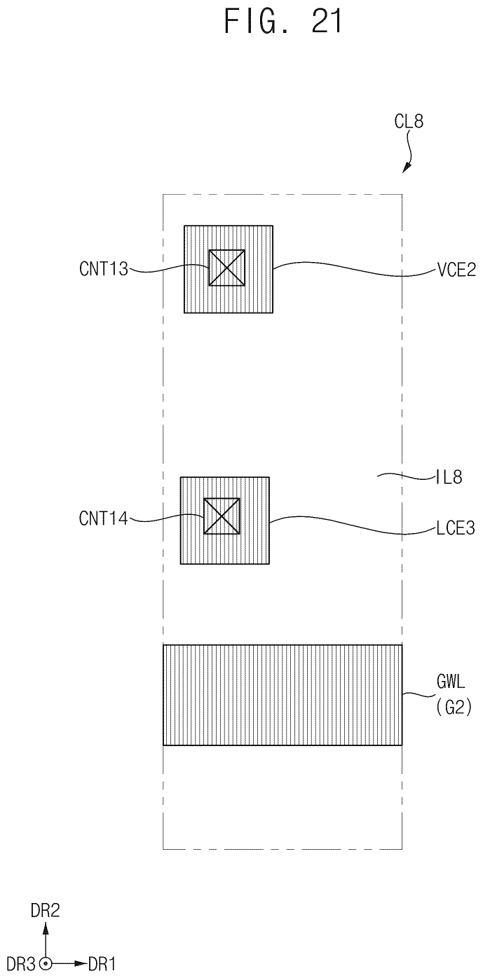

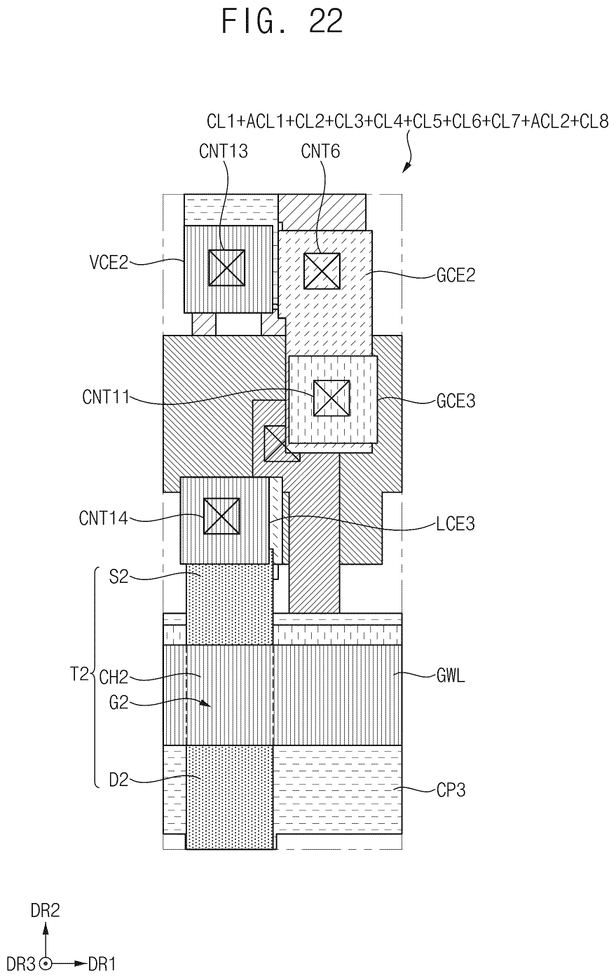

FIG. 21 is a layout view illustrating the eighth conductive layer CL8. FIG. 22 is a layout view in which the eighth conductive layer CL8 is further arranged on the second active layer ACL2 of FIG. 20.

As illustrated in FIGS. 3, 21, and 22, the eighth conductive layer CL8 may be arranged on the second active layer ACL2. For example, the eighth conductive layer CL8 may be arranged on the eighth insulating layer IL8.

The eighth conductive layer CL8 may include a conductive material, such as a metal, an alloy, a conductive metal nitride, a conductive metal oxide, a transparent conductive oxide, or the like. These may be used alone or in any suitable combination with each other. For example, the eighth conductive layer CL8 may be referred to as a sixth gate conductive layer.

The eighth conductive layer CL8 may include a second driving voltage connection electrode VCE2, a third light-emitting element connection electrode LCE3, and the first gate line GWL. The second driving voltage connection electrode VCE2, the third light-emitting element connection electrode LCE3, and the first gate line GWL may be spaced apart from each other in a plan view.

As illustrated in FIGS. 18 and 22, the second driving voltage connection electrode VCE2 may overlap with the first driving voltage connection electrode VCE1 in a plan view. The second driving voltage connection electrode VCE2 may be connected to the first driving voltage connection electrode VCE1 through a thirteenth contact hole CNT13 that penetrates a lower insulating layer (e.g., the seventh insulating layer IL7 and the eighth insulating layer IL8). In other words, the thirteenth contact hole CNT13 may expose a portion of the first driving voltage connection electrode VCE1, and a portion of the second driving voltage connection electrode VCE2 may contact the portion of the first driving voltage connection electrode VCE1 through the thirteenth contact hole CNT13.

As illustrated in FIG. 22, the third light-emitting element connection electrode LCE3 may overlap with the second light-emitting element connection electrode LCE2 in a plan view. The third light-emitting element connection electrode LCE3 may be connected to the second light-emitting element connection electrode LCE2 through a fourteenth contact hole CNT14 that penetrates a lower insulating layer (e.g., the seventh insulating layer IL7 and the eighth insulating layer IL8). In other words, the fourteenth contact hole CNT14 may expose a portion of the second light-emitting element connection electrode LCE2, and a portion of the third light-emitting element connection electrode LCE3 may contact the portion of the second light-emitting element connection electrode LCE2 through the fourteenth contact hole CNT14.

The first gate line GWL may extend in the first direction DR1. The write gate signal GW of FIG. 2 may be applied to the first gate line GWL.

As illustrated in FIGS. 20 and 22, a portion of the first gate line GWL may overlap with the second channel area CH2 of the second active pattern ACT2 in a plan view. The portion of the first gate line GWL overlapping with the second channel area CH2 may be a second gate electrode G2. The second gate electrode G2 may be the gate electrode of the second transistor T2 of FIG. 2.

The ninth insulating layer IL9 may be arranged on the eighth conductive layer CL8. The ninth insulating layer IL9 may cover the second driving voltage connection electrode VCE2, the third light-emitting element connection electrode LCE3, and the first gate line GWL. The ninth insulating layer IL9 may include an inorganic insulating material and/or an organic insulating material.

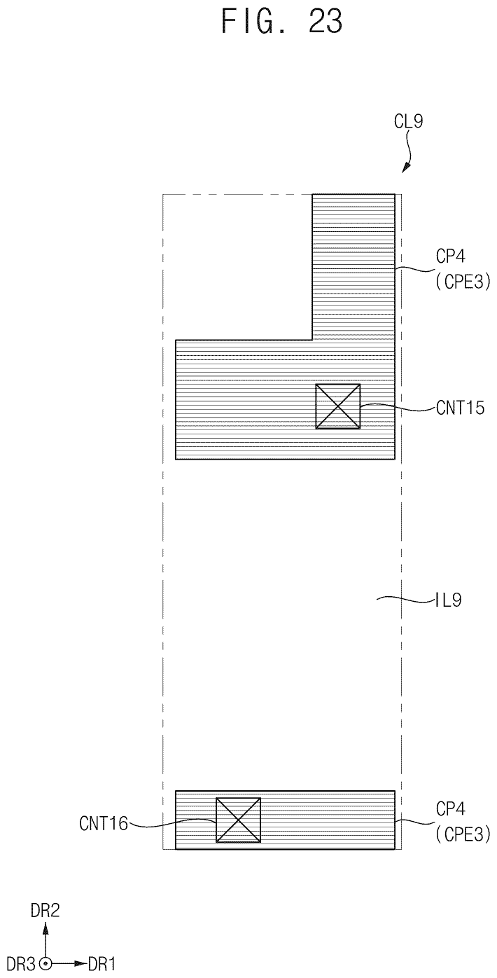

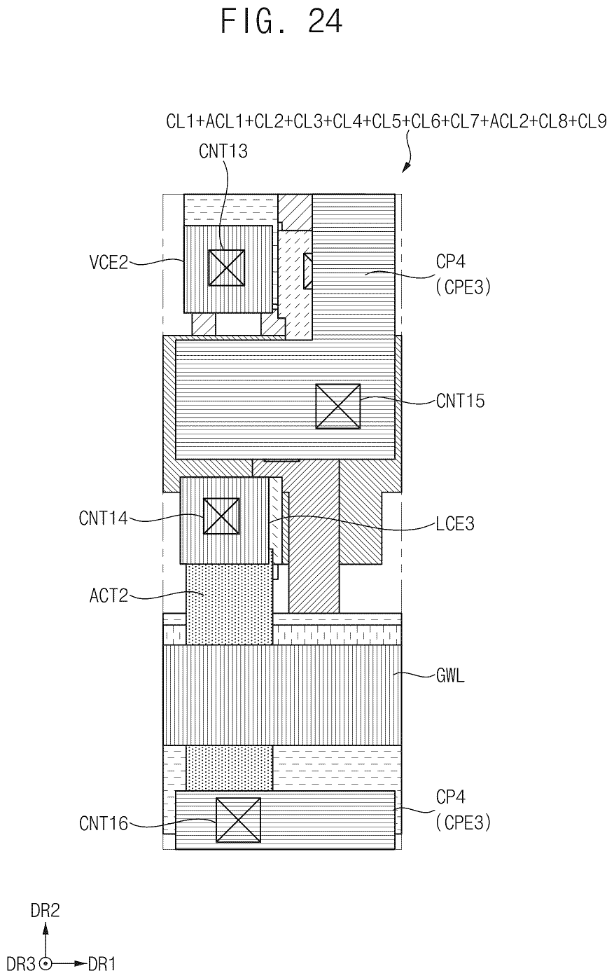

FIG. 23 is a layout view illustrating the ninth conductive layer CL9. FIG. 24 is a layout view in which the ninth conductive layer CL9 is further arranged on the eighth conductive layer CL8 of FIG. 22.

As illustrated in FIGS. 3, 23, and 24, the ninth conductive layer CL9 may be arranged on the eighth conductive layer CL8. For example, the ninth conductive layer CL9 may be arranged on the ninth insulating layer IL9.

The ninth conductive layer CL9 may include a conductive material, such as a metal, an alloy, a conductive metal nitride, a conductive metal oxide, a transparent conductive oxide, or the like. These may be used alone or in any suitable combination with each other. For example, the ninth conductive layer CL9 may be referred to as a first source drain conductive layer.

The ninth conductive layer CL9 may include a fourth conductive pattern CP4. As illustrated in FIGS. 18 and 24, the fourth conductive pattern CP4 may overlap with the third gate connection electrode GCE3 in a plan view. The fourth conductive pattern CP4 may be connected to the third gate connection electrode GCE3 through a fifteenth contact hole CNT15 that penetrates a lower insulating layer (e.g., the seventh insulating layer IL7, the eighth insulating layer IL8, and the ninth insulating layer IL9). In other words, the fifteenth contact hole CNT15 may expose a portion of the third gate connection electrode GCE3, and a first portion of the fourth conductive pattern CP4 may contact the portion of the third gate connection electrode GCE3. As described in more detail below, the fourth conductive pattern CP4 may be a first electrode CPE3 of the second capacitor C2.

In an embodiment, the first electrode CPE3 of the second capacitor C2 may be electrically connected to the lower conductive pattern BML (e.g., the lower gate electrode BG1 of the first transistor T1) through one or more gate connection electrodes. For example, the first electrode CPE3 of the second capacitor C2 may be electrically connected to the lower conductive pattern BML (e.g., the lower gate electrode BG1 of the first transistor T1) through the third gate connection electrode GCE3, the second gate connection electrode GCE2, and the first gate connection electrode GCE1.

As illustrated in FIG. 24, the fourth conductive pattern CP4 may overlap with the second drain area D2 of the second active pattern ACT2 in a plan view. The fourth conductive pattern CP4 may be connected to the second drain area D2 (e.g., the second electrode of the second transistor T2) through a sixteenth contact hole CNT16 that penetrates a lower insulating layer (e.g., the eighth insulating layer IL8 and the ninth insulating layer IL9). In other words, the sixteenth contact hole CNT16 may expose a portion of the second drain area D2, and a second portion of the fourth conductive pattern CP4 may contact the portion of the second drain area D2.

The second electrode of the second transistor T2 may be electrically connected to the lower conductive pattern BML (e.g., the lower gate electrode BG1 of the first transistor T1) through the fourth conductive pattern CP4, the third gate connection electrode GCE3, the second gate connection electrode GCE2, and the first gate connection electrode GCE1. In other words, the second electrode of the second transistor T2 may provide the data voltage VDATA of FIG. 2 to the first electrode CPE3 of the second capacitor C2, and the first electrode CPE3 of the second capacitor C2 may provide the data voltage VDATA to the lower conductive pattern BML (e.g., the lower gate electrode BG1 of the first transistor T1) through the gate connection electrodes GCE1, GCE2, and GCE3.

The tenth insulating layer IL10 may be arranged on the ninth conductive layer CL9. The tenth insulating layer IL10 may cover the fourth conductive pattern CP4. The tenth insulating layer IL10 may include an inorganic insulating material and/or an organic insulating material.

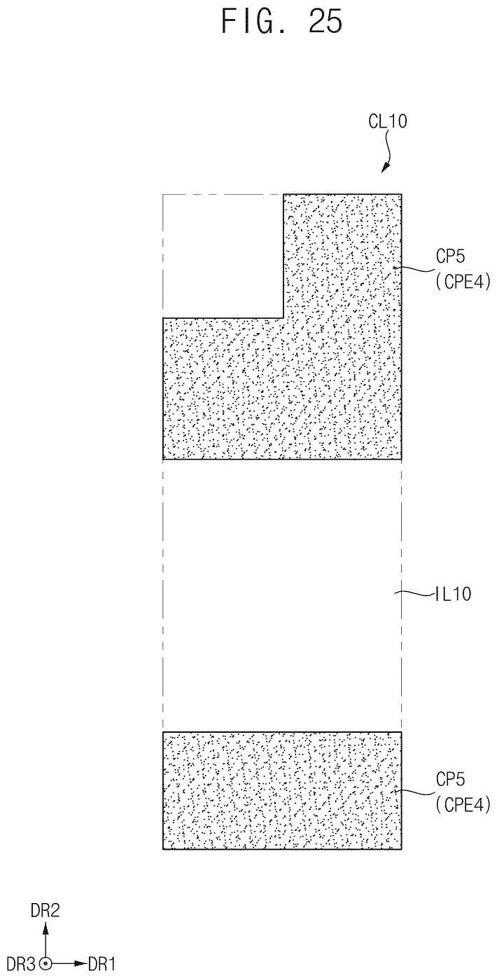

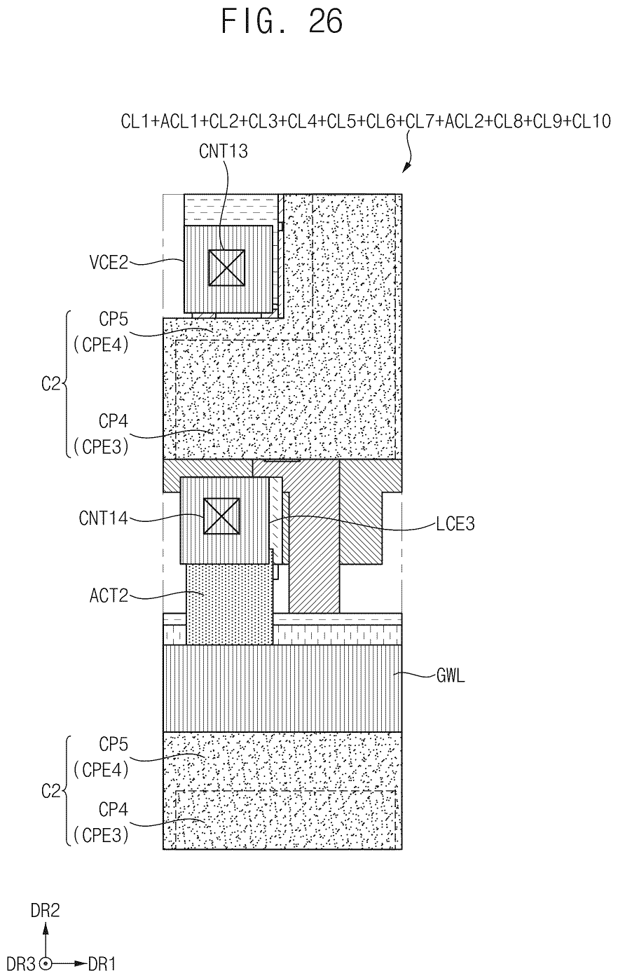

FIG. 25 is a layout view illustrating the tenth conductive layer CL10. FIG. 26 is a layout view in which the tenth conductive layer CL10 is further arranged on the ninth conductive layer CL9 of FIG. 24.

As illustrated in FIGS. 3, 25, and 26, the tenth conductive layer CL10 may be arranged on the ninth conductive layer CL9. For example, the tenth conductive layer CL10 may be arranged on the tenth insulating layer IL10.

The tenth conductive layer CL10 may include a conductive material, such as a metal, an alloy, a conductive metal nitride, a conductive metal oxide, a transparent conductive oxide, or the like. These may be used alone or in any suitable combination with each other. For example, the tenth conductive layer CL10 may be referred to as a second capacitor electrode layer.

The tenth conductive layer CL10 may include a fifth conductive pattern CP5. As illustrated in FIGS. 24 and 26, the fifth conductive pattern CP5 may overlap with the fourth conductive pattern CP4 in a plan view. The fifth conductive pattern CP5 may be spaced apart from the fourth conductive pattern CP4 by the tenth insulating layer IL10. The fourth conductive pattern CP4 and the fifth conductive pattern CP5 may form the second capacitor C2. In other words, the fourth conductive pattern CP4 may be the first electrode CPE3 of the second capacitor C2, and the fifth conductive pattern CP5 may be a second electrode CPE4 of the second capacitor C2. In an embodiment, the reference voltage VREF of FIG. 2 may be applied to the fifth conductive pattern CP5 (e.g., the second electrode CPE4 of the second capacitor C2).

In an embodiment, the second capacitor C2 may be arranged on the second active pattern ACT2.

In an embodiment, as illustrated in FIGS. 16 and 26, the second capacitor C2 may at least partially overlap with the first capacitor C1 in a plan view. Accordingly, the integration of the pixel driving circuits PC (e.g., refer to FIG. 2) included in the display panel DP may be further improved.

In an embodiment, the fifth conductive pattern CP5 may be formed as the separate second capacitor electrode layer that does not configure the transistors (e.g., the first to third transistors T1, T2, and T3). In other words, the second electrode CPE4 of the second capacitor C2 may be formed in the separate second capacitor electrode layer that does not configure the transistors. Accordingly, the capacitance of the second capacitor C2 may be relatively increased.

The eleventh insulating layer IL11 may be arranged on the tenth conductive layer CL10. The eleventh insulating layer IL11 may cover the fifth conductive pattern CP5. The eleventh insulating layer IL11 may include an inorganic insulating material and/or an organic insulating material.

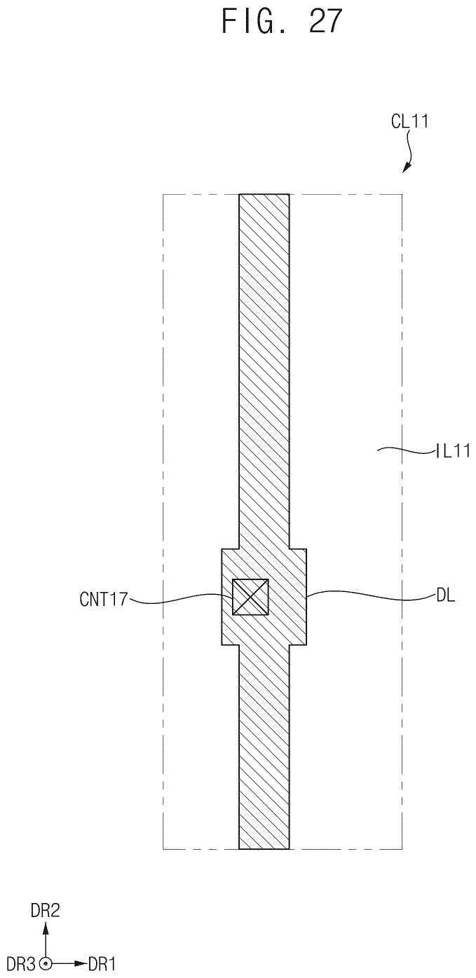

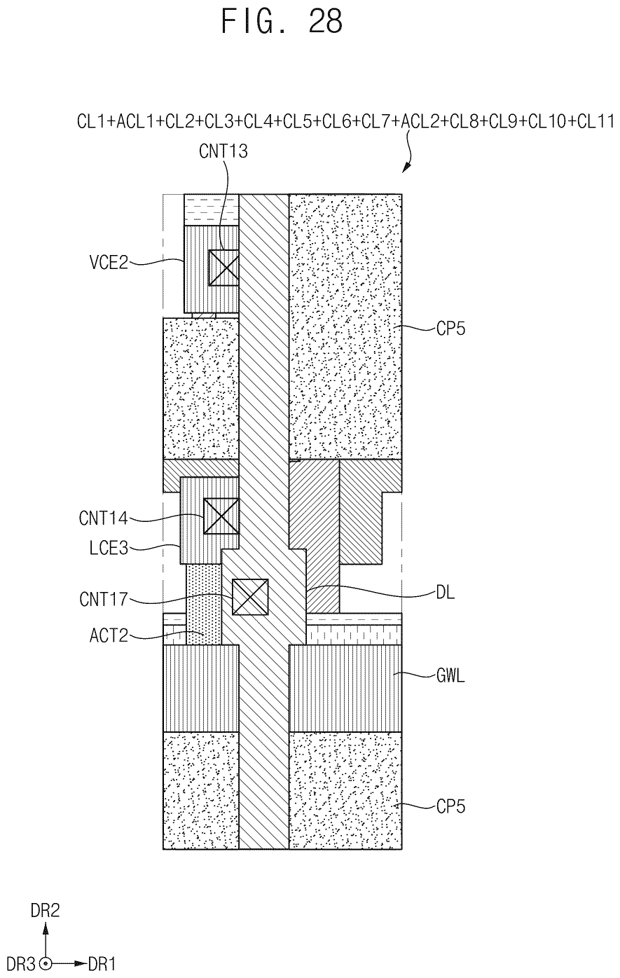

FIG. 27 is a layout view illustrating the eleventh conductive layer CL11. FIG. 28 is a layout view in which the eleventh conductive layer CL11 is further arranged on the tenth conductive layer CL10 of FIG. 26.

As illustrated in FIGS. 3, 27, and 28, the eleventh conductive layer CL11 may be arranged on the tenth conductive layer CL10. For example, the eleventh conductive layer CL11 may be arranged on the eleventh insulating layer IL11.

The eleventh conductive layer CL11 may include a conductive material, such as a metal, an alloy, a conductive metal nitride, a conductive metal oxide, a transparent conductive oxide, or the like. These may be used alone or in any suitable combination with each other. For example, the eleventh conductive layer CL11 may be referred to as a second source drain conductive layer.

The eleventh conductive layer CL11 may include the data line DL. The data line DL may extend in the second direction DR2. The data voltage VDATA of FIG. 2 may be applied to the data line DL.

As illustrated in FIGS. 20 and 28, the data line DL may overlap with the second source area S2 of the second active pattern ACT2 in a plan view. The data line DL may be connected to the second source area S2 through a seventeenth contact hole CNT17 that penetrates a lower insulating layer (e.g., the eighth to eleventh insulating layers IL8, IL9, IL10, and IL11). In other words, the seventeenth contact hole

CNT17 may expose a portion of the second source area S2, and a portion of the data line DL may contact the portion of the second source area S2 through the seventeenth contact hole CNT17.

Accordingly, the data line DL may provide the data voltage to the second source area S2 of the second active pattern ACT2 (e.g., the first electrode of the second transistor T2).

In an embodiment, the second capacitor C2 may be arranged between the data line DL and the second active pattern ACT2.

The twelfth insulating layer IL12 may be arranged on the eleventh conductive layer CL11. The twelfth insulating layer IL12 may cover the data line DL. The twelfth insulating layer IL12 may include an inorganic insulating material and/or an organic insulating material.

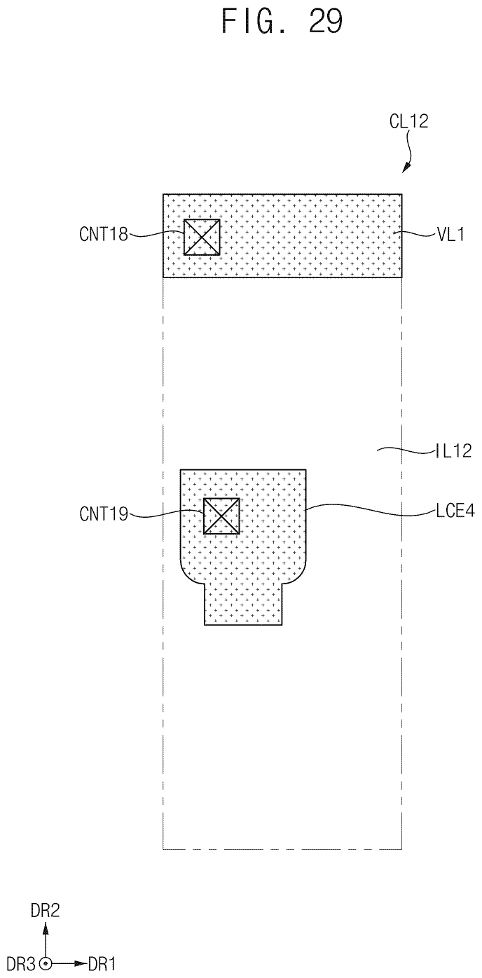

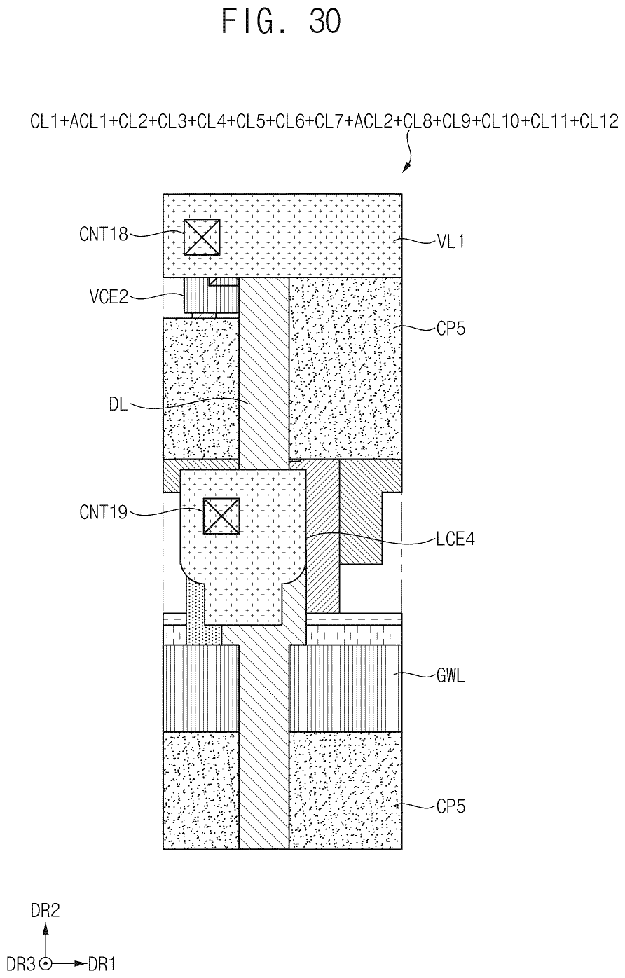

FIG. 29 is a layout view illustrating the twelfth conductive layer CL12. FIG. 30 is a layout view in which the twelfth conductive layer CL12 is further arranged on the eleventh conductive layer CL11 of FIG. 28.

As illustrated in FIGS. 3, 29, and 30, the twelfth conductive layer CL12 may be arranged on the eleventh conductive layer CL11. For example, the twelfth conductive layer CL12 may be arranged on the twelfth insulating layer IL12.

The twelfth conductive layer CL12 may include a conductive material, such as a metal, an alloy, a conductive metal nitride, a conductive metal oxide, a transparent conductive oxide, or the like. These may be used alone or in any suitable combination with each other. For example, the twelfth conductive layer CL12 may be referred to as a third source drain conductive layer.

The twelfth conductive layer CL12 may include the first voltage line VL1 and a fourth light-emitting element connection electrode LCE4. The first voltage line VL1 and the fourth light-emitting element connection electrode LCE4 may be spaced apart from each other in a plan view.

The first voltage line VL1 may extend in the first direction DR1. The driving voltage ELVDD of FIG. 2 may be applied to the first voltage line VL1. As illustrated in FIGS. 22 and 30, the first voltage line VL1 may overlap with the second driving voltage connection electrode VCE2 in a plan view. The first voltage line VL1 may be connected to the second driving voltage connection electrode VCE2 through an eighteenth contact hole CNT18 that penetrates a lower insulating layer (e.g., the ninth to twelfth insulating layers IL9, IL10, IL11, and IL12). In other words, the eighteenth contact hole CNT18 may expose a portion of the second driving voltage connection electrode VCE2, and a portion of the first voltage line VL1 may contact the portion of the second driving voltage connection electrode VCE2 through the eighteenth contact hole CNT18.

Accordingly, the first voltage line VL1 may provide the driving voltage to the second electrode CPE2 of the first capacitor C1 through the driving voltage connection electrode. For example, the first voltage line VL1 may provide the driving voltage to the third conductive pattern CP3 (e.g., the second electrode CPE2 of the first capacitor C1) through the second driving voltage connection electrode VCE2 and the first driving voltage connection electrode VCE1. In addition, the driving voltage may be applied to the first source area S1 of the first active pattern ACT1 (e.g., the first electrode of the first transistor T1) through the first voltage line VL1, the second driving voltage connection electrode VCE2, the first driving voltage connection electrode VCE1, the third conductive pattern CP3, and the second connection pattern CNP2.

In an embodiment, the second capacitor C2 may be arranged between the first voltage line VL1 and the second active pattern ACT2.

As illustrated in FIGS. 22 and 30, the fourth light-emitting element connection electrode LCE4 may overlap with the third light-emitting element connection electrode LCE3 in a plan view. The fourth light-emitting element connection electrode LCE4 may be connected to the third light-emitting element connection electrode LCE3 through a nineteenth contact hole CNT19 that penetrates a lower insulating layer (e.g., the ninth to twelfth insulating layers IL9, IL10, IL11, and IL12). In other words, the nineteenth contact hole CNT19 may expose a portion of the third light-emitting element connection electrode LCE3, and a portion of the fourth light-emitting element connection electrode LCE4 may contact the portion of the third light-emitting element connection electrode LCE3 through the nineteenth contact hole CNT19.

The thirteenth insulating layer IL13 may be arranged on the twelfth conductive layer CL12. The thirteenth insulating layer IL13 may cover the first voltage line VL1 and the fourth light-emitting element connection electrode LCE4. The thirteenth insulating layer IL13 may include an inorganic insulating material and/or an organic insulating material.

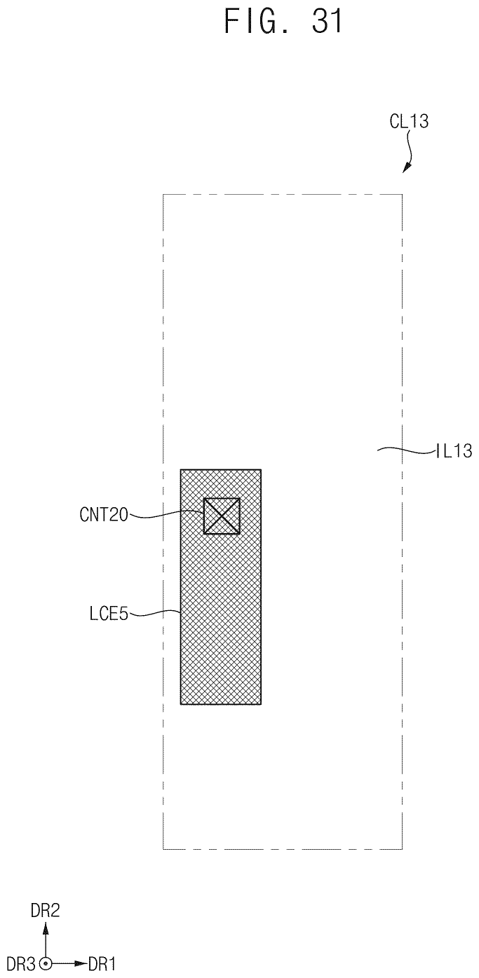

FIG. 31 is a layout view illustrating the thirteenth conductive layer CL13.

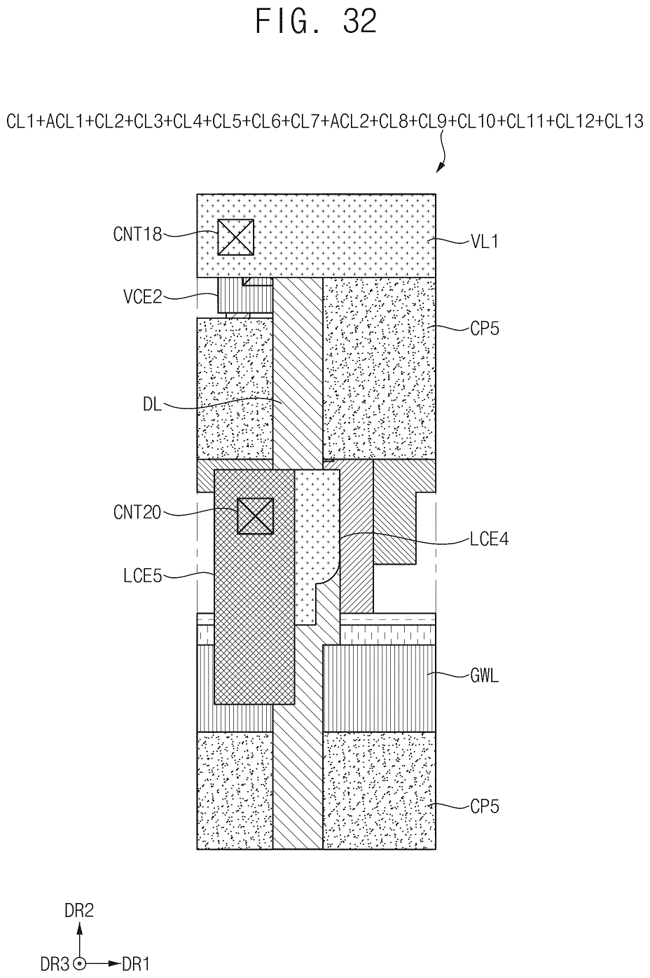

FIG. 32 is a layout view in which the thirteenth conductive layer CL13 is further arranged on the twelfth conductive layer CL12 of FIG. 30.

As illustrated in FIGS. 3, 31, and 32, the thirteenth conductive layer CL13 may be arranged on the twelfth conductive layer CL12. For example, the thirteenth conductive layer CL13 may be arranged on the thirteenth insulating layer IL13.

The thirteenth conductive layer CL13 may include a conductive material, such as a metal, an alloy, a conductive metal nitride, a conductive metal oxide, a transparent conductive oxide, or the like. These may be used alone or in any suitable combination with each other. The thirteenth conductive layer CL13 may be referred to as a fourth source drain conductive layer.

The thirteenth conductive layer CL13 may include a fifth light-emitting element connection electrode LCE5. As illustrated in FIGS. 30 and 32, the fifth light-emitting element connection electrode LCE5 may overlap with the fourth light-emitting element connection electrode LCE4 in a plan view. The fifth light-emitting element connection electrode LCE5 may be connected to the fourth light-emitting element connection electrode LCE4 through a 20th contact hole CNT20 that penetrates a lower insulating layer (e.g., the thirteenth insulating layer IL13). In other words, the 20th contact hole CNT20 may expose a portion of the fourth light-emitting element connection electrode LCE4, and a portion of the fifth light-emitting element connection electrode LCE5 may contact the portion of the fourth light-emitting element connection electrode LCE4 through the 20th contact hole CNT20.

The fourteenth insulating layer IL14 may be arranged on the thirteenth conductive layer CL13. The fourteenth insulating layer IL14 may cover the fifth light-emitting element connection electrode LCE5. The 14th insulating layer IL14 may include an inorganic insulating material and/or an organic insulating material.

As illustrated in FIG. 3, the pixel electrode E1 may be arranged on the fourteenth insulating layer IL14. The pixel electrode E1 may include a conductive material, such as a metal, an alloy, a conductive metal nitride, a conductive metal oxide, a transparent conductive oxide, or the like. These may be used alone or in any suitable combination with each other.

The pixel electrode E1 may be connected to the fifth light-emitting element connection electrode LCE5 through a contact hole that penetrates a lower insulating layer (e.g., the fourteenth insulating layer IL14). Accordingly, the pixel electrode E1 may be electrically connected to the first drain area D1 (e.g., the second electrode of the first transistor T1) and the third source area S3 (e.g., the first electrode of the third transistor T3) of the first active pattern ACT1 through the fifth light-emitting element connection electrode LCE5, the fourth light-emitting element connection electrode LCE4, the third light-emitting element connection electrode LCE3, the second light-emitting element connection electrode LCE2, the first light-emitting element connection electrode LCE1, and the third connection pattern CNP3. For example, the pixel electrode E1 may be the anode of the light-emitting element LD of FIG. 2.

The pixel defining layer PDL may be arranged on the fourteenth insulating layer IL14 and the pixel electrode E1. The pixel defining layer PDL may cover an edge of the pixel electrode E1, and may expose an upper surface of the pixel electrode E1. The pixel defining layer PDL may include an inorganic insulating material and/or an organic insulating material.

The light-emitting layer EML may be arranged on the pixel electrode E1. The light-emitting layer EML may emit light having a suitable color (e.g., a specific or predetermined color), such as, for example, red, green, blue, white, or the like. In an embodiment, the light-emitting layer EML may include at least one of an organic light-emitting material or a quantum dot.

In an embodiment, the light-emitting element layer may further include functional layers (e.g., a hole injection layer, a hole transport layer, an electron transport layer, an electron injection layer, or the like) arranged at an upper portion of the light-emitting layer EML and/or a lower portion of the light-emitting layer EML.

The common electrode E2 may be arranged on the pixel defining layer PDL and the light-emitting layer EML. The common electrode E2 may cover the pixel defining layer PDL and the light-emitting layer EML, and may be arranged along the profiles of the pixel defining layer PDL and the light-emitting layer EML with a uniform or substantially uniform thickness. The common electrode E2 may include a conductive material, such as a metal, an alloy, a conductive metal nitride, a conductive metal oxide, a transparent conductive oxide, or the like. These may be used alone or in any suitable combination with each other. For example, the common electrode E2 may be the cathode of the light-emitting element LD of FIG. 2. The pixel electrode E1, the light-emitting layer EML, and the common electrode E2 may configure the light-emitting element LD.

According to some embodiments, the integration of the pixel driving circuits PC (e.g., refer to FIG. 2) included in the display panel DP may be further improved. In other words, an area where one pixel driving circuit PC is arranged may be relatively reduced. For example, a length in the first direction DR1 of the area where one pixel driving circuit PC is arranged may be about 5.64 micrometers, and a length in the second direction DR2 of the area where one pixel driving circuit PC is arranged may be about 16.92 micrometers. However, the present disclosure is not limited thereto. As the integration of the pixel driving circuits PC is improved, the resolution of the display device DD may be improved. For example, the resolution of the display device DD may be greater than or equal to about 1500 pixels per inch (PPI).

FIG. 33 is a block diagram illustrating an electronic device according to an embodiment of the present disclosure.

Referring to FIG. 33, an electronic device 10 according to an embodiment may include a display module 11, a processor 12, a memory 13, and a power module 14. The display device according to an embodiment may be applied to a variety of suitable electronic devices. The electronic device 10 according to an embodiment may include the display device as described above, and may further include other modules or devices having other additional functions in addition to the display device.

The processor 12 may include at least one of a central processing unit (CPU), an application processor (AP), a graphic processing unit (GPU), a communication processor (CP), an image signal processor (ISP), or a controller.

The memory 13 may store data information used for the operations of the processor 12 or the display module 11. When the processor 12 executes an application stored in the memory 13, an image data signal and/or an input control signal may be transmitted to the display module 11, and the display module 11 may process the received signals to output image information through a display screen.

The power module 14 may include a power supply module (e.g., a power supply or a power supply circuit), such as a power adapter, a battery device, and/or the like, and a power conversion module (e.g., a power converter or a power conversion circuit) that converts power supplied by the power supply module to generate the power used for the operations of the electronic device 10. In other words, the power module 14 may provide power to the display device according to some of the embodiments described above.

At least one of the components of the electronic device 10 described above may be included in the display device according to some of the embodiments described above. In addition, some of the individual modules that are functionally included in one module may be included in the display device, and others may be provided separately from the display device. For example, the display device may include the display module 11, and the processor 12, the memory 13, and the power module 14 may be provided in the form of other devices in the electronic device 10 other than the display device.

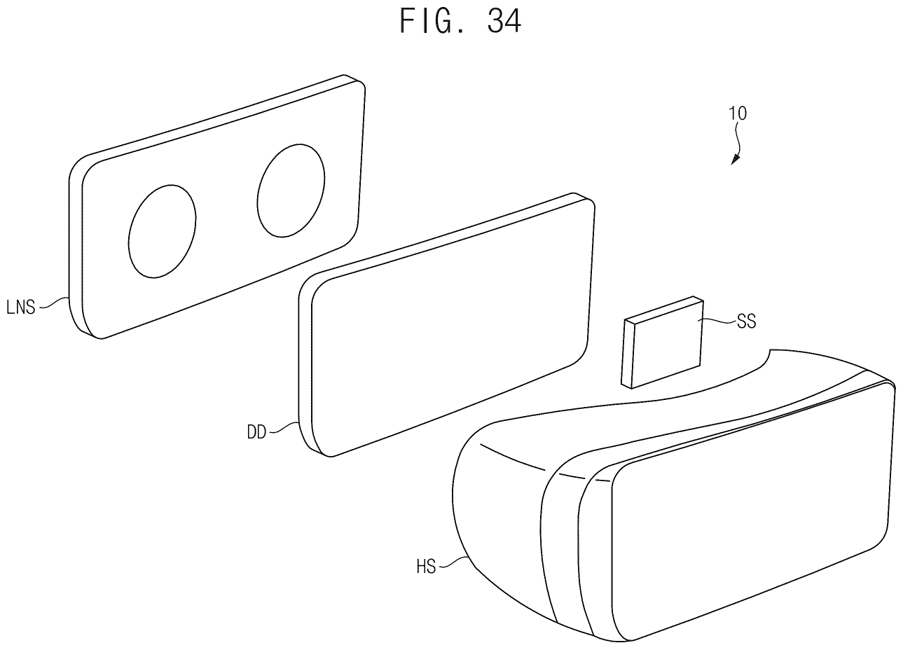

FIG. 34 is an exploded perspective view illustrating an electronic device according to an embodiment of the present disclosure.

Referring to FIG. 34, the electronic device 10 according to an embodiment of the present disclosure may include a lens part LNS, the display device DD, a sensor part SS, and a housing HS. In an embodiment, the electronic device 10 may be an electronic device for virtual reality (VR) or augmented reality (AR), and may be worn in the form of glasses, a helmet, or the like.

The display device DD may be arranged to be adjacent to the lens part LNS. The display device DD may be the display device DD described above with reference to FIGS. 1 to 32. In other words, the display device DD described above with reference to FIGS. 1 to 32 may be implemented as a head-mounted display device.

For example, the sensor part SS may include a camera. However, the present disclosure is not limited thereto, and the sensor part SS may include various suitable kinds of sensors capable of tracking a user's gaze.

The housing HS may accommodate the lens part LNS, the display device DD, and the sensor part SS. In FIG. 34, the lens part LNS, the display device DD, and the sensor part SS are illustrated as being accommodated on one side of the housing HS, but the present disclosure is not limited thereto.

Some embodiments of the present disclosure described above may be applied to various suitable display devices or electronic devices. For example, some embodiments of the present disclosure may be applicable to various suitable display devices or electronic devices, such as display devices for vehicles, ships, and aircrafts, portable communication devices, display devices for exhibition or information transmission, medical display devices, and the like.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a lower conductive pattern on the substrate;
a first active pattern on the lower conductive pattern;
a first gate electrode on the first active pattern;
a first capacitor on the first active pattern, and comprising:
a first electrode electrically connected to the first gate electrode; and
a second electrode on the first electrode, and configured to receive a driving voltage;
a second active pattern on the first active pattern;
a second capacitor on the first capacitor, and comprising:
a first electrode electrically connected to the second active pattern; and
a second electrode on the first electrode, and configured to receive a reference voltage; and
a light-emitting element on the second capacitor.

2. The display device of claim 1, wherein the first electrode of the second capacitor is electrically connected to the lower conductive pattern through a gate connection electrode.

3. The display device of claim 1, wherein the first capacitor is located between the first active pattern and the second active pattern, and
wherein the second capacitor is located on the second active pattern.

4. The display device of claim 1, wherein the second capacitor at least partially overlaps with the first capacitor in a plan view.

5. The display device of claim 1, wherein the second active pattern at least partially overlaps with the first active pattern in a plan view.

6. The display device of claim 1, further comprising a first voltage line on the second active pattern, and configured to:
receive the driving voltage; and
apply the driving voltage to the second electrode of the first capacitor through a driving voltage connection electrode.

7. The display device of claim 6, wherein the second capacitor is located between the first voltage line and the second active pattern.

8. The display device of claim 1, wherein the first active pattern comprises a silicon semiconductor material, and
wherein the second active pattern comprises an oxide semiconductor material.

9. The display device of claim 1,
wherein the first active pattern comprises:
a first source area;
a first drain area;
a first channel area between the first source area and the first drain area;
a third source area connected to the first drain area;
a third drain area; and
a third channel area between the third source area and the third drain area, and
wherein the second active pattern comprises:
a second source area;
a second drain area; and
a second channel area between the second source area and the second drain area.

10. The display device of claim 9, further comprising a first connection pattern electrically connecting the third drain area of the first active pattern and the first gate electrode to each other.

11. The display device of claim 10, wherein the first electrode of the first capacitor is electrically connected to the third drain area of the first active pattern through the first connection pattern.

12. The display device of claim 9, further comprising a second connection pattern electrically connecting the first source area of the first active pattern and the second electrode of the first capacitor to each other.

13. The display device of claim 12, wherein the first capacitor is located between the second connection pattern and the second active pattern.

14. The display device of claim 9, further comprising a third connection pattern connected to the first drain area and the third source area of the first active pattern,
wherein the third connection pattern is electrically connected to the light-emitting element through a light-emitting element connection electrode.

15. The display device of claim 9, wherein the lower conductive pattern, the first source area, the first channel area, the first drain area, and the first gate electrode define a first transistor configured to provide a driving current to the light-emitting element.

16. The display device of claim 15,
wherein the lower conductive pattern comprises a lower gate electrode of the first transistor,
wherein the first gate electrode comprises an upper gate electrode of the first transistor, and
wherein the first channel area comprises a channel of the first transistor.

17. The display device of claim 15, further comprising a second gate electrode between the second active pattern and the first electrode of the second capacitor,
wherein the second source area, the second channel area, the second drain area, and the second gate electrode define a second transistor configured to apply a data voltage to the first transistor in response to a write gate signal.

18. The display device of claim 17,
wherein the second transistor is configured to apply the data voltage to the first electrode of the second capacitor, and
wherein the first electrode of the second capacitor is configured to apply the data voltage to the lower conductive pattern through a gate connection electrode.

19. The display device of claim 15, further comprising a third gate electrode located in a same layer as that of the first gate electrode,
wherein the third source area, the third channel area, the third drain area, and the third gate electrode define a third transistor configured to diode-connect the first transistor in response to a compensation gate signal.

20. An electronic device comprising:
a display device comprising a light-emitting element; and
a processor configured to transmit an image data signal and an input control signal to the display device,
wherein the display device comprises:
a substrate;
a lower conductive pattern on the substrate;
a first active pattern on the lower conductive pattern;
a first gate electrode on the first active pattern;
a first capacitor on the first active pattern, and comprising:
a first electrode electrically connected to the first gate electrode; and
a second electrode on the first electrode, and configured to receive a driving voltage;
a second active pattern on the first active pattern;
a second capacitor on the first capacitor, and comprising:
a first electrode electrically connected to the second active pattern; and
a second electrode on the first electrode, and configured to receive a reference voltage; and
the light-emitting element on the second capacitor.
